(19) United States
(12) Patent Application Publication
(10) Pub. No.: US 2012/0167949 A1
(43) Pub. Date: Jul. 5, 2012

(54) METHOD OF ENHANCING IRRADIANCE PROFILE FROM SOLAR CONCENTRATOR

(75) Inventors: Paul Dentinger, Sunol, CA (US); James Page, Oakland, CA (US); John Liptac, Mountain House, CA (US); Stuart Maestas, Pleasanton, CA (US)

(73) Assignee: COOLEARTH SOLAR, Livermore, CA (US)

(21) Appl. No.: 13/338,607

(22) Filed: Dec. 28, 2011

Related U.S. Application Data
(60) Provisional application No. 61/428,203, filed on Dec. 29, 2010.

(51) Int. Cl. G02B 5/10; B32B 37/14; H01L 31/0232; B29D 11/00

(52) U.S. Cl. 136/246; 264/2.7; 264/1.9; 156/145; 359/853

(57) ABSTRACT

Embodiments of the present invention include structures and methods for enhancing illumination uniformity from solar concentrators. Certain embodiments may use features on a reflective layer to globally correct for deviation in reflective behavior from a desired shape. Local features such as facets on a reflective layer are formed such that the resulting illumination profile represents a superposition of multiple facets. Features may be formed on a back film to correct the reflectance of the back film. In some embodiments, features may be formed on a front film to correct a profile from refraction. In some embodiments the corrections are for line concentrators. Global and local correction techniques may be used together, and may be used on front film or reflective film(s) together or separately. Global and/or local correction may also be used in combination with other approaches, such as secondary optic receiver compensation.

### CROSS-REFERENCES TO RELATED APPLICATIONS

This application claims benefit under 35 U.S.C. §119(e) of U.S. Provisional Patent Application No. 61/428,203 filed on Dec. 29, 2010, the contents of which are incorporated by reference herein in their entirety for all purposes.

### BACKGROUND

Solar radiation is an abundant energy source. However, attempts to harness solar power on large scales have so far failed to be economically competitive with most fossil-fuel energy sources.

One reason for the lack of adoption of solar energy sources on a large scale is that fossil-fuel energy sources have the advantage of economic externalities, such as government subsidies including low-cost or cost-free pollution and emission. Another reason for the lack of adoption of solar energy sources on a large scale is that the solar flux is not intense enough for direct conversion at one solar flux to be cost effective. Solar energy concentrator technology has sought to address this issue. For example, solar radiation energy is easily manipulated and concentrated using refraction, diffraction, or reflection to produce solar radiation energy having many thousands of times the initial flux. This can be done using only modest materials such as refractors, diffractors and reflectors.

With so many possible approaches, there have been a multitude of previous attempts to implement low cost solar energy concentrators. So far, however, solar concentrator systems cost too much to compete unsubsidized with fossil fuels, in part because of large amounts of material and large areas that that solar collectors occupy. The large amounts of materials used to make solar concentration systems and the large areas that are occupied by solar concentration systems render solar concentration systems unsuitable for large-scale solar farming.

Attempts at reducing the amount of materials used in solar concentration systems and the large areas that they occupy include using flat reflective films that assume a smooth concave shape under inflation pressure. Thus in certain approaches, inflation air may be used to impart a curved profile to a reflective component of a concentrator for a solar collector structure. Such inflatable solar concentrators may offer certain benefits over conventional concentrator designs because they employ common structural elements and therefore help in reducing cost of the solar concentrator. Additionally, since inflatable concentrators use air as a structural member, lower cost thin plastic membranes (here referred to as films) can be used as a primary reflector. This can yield significant weight advantages in a system deployed in the field. The weight advantages in the concentrator itself can in turn reduce the complexity of structures used for mounting and tracking systems, thereby reducing the overall mass of the system and hence its cost.

Inflatable concentrators can be more cost effective, but inflatable concentrators are subject to the shape the inflation pressure produces, which can produce non-uniform concentrated light as compared with non-inflatable concentrators. In particular, the shape of the inflated primary mirror may result in an irregular illumination profile on the receiver. This irregular illumination profile in turn may yield lower efficiency of the solar receiver and overall lower system efficiency.

Accordingly, there exists a need in the art for improved methods for optimizing reflectance profiles of concentrator designs while maintaining low cost.

### SUMMARY

Embodiments of the present invention include structures and methods that enhance irradiation uniformity from solar concentrators, and in particular, inflatable solar concentrators. Certain embodiments may use features formed on a reflective layer of the solar concentrator to globally correct for deviation in reflective behavior from a desired shape. According to one example, the features may correct reflective behavior of a Hencky-type surface of an inflated thin film, to match a specific desired surface that creates a specific desired reflected light distribution across a receiver. In some embodiments, local features such as facets may be formed on a reflective layer, such that the resulting illumination profile represents a superposition of multiple facets. The latter approach minimizes non-uniform illumination resulting from shading. In certain embodiments, the features may be formed by embossing a film. In some embodiments features may be formed on a front film to correct the reflectance of a back film. In certain embodiments the features may correct the profile of point focus concentrators or line focus concentrators. Global and local correction techniques may be used together, and may be used on front film or reflective film(s) together or separately, on point focus or line focus systems. Global and/or local correction may also be used in combination with other approaches, such as secondary optic receiver compensation.

Some embodiments of the present invention provide an apparatus. The apparatus comprises a reflective solar light concentrator having a physical shape and a feature formed in or on the reflective solar light concentrator to match optical behavior of the physical shape to optical behavior of a desired shape. The apparatus may also include an upper transparent portion that allows light to penetrate and reach the reflective solar light concentrator.

Other embodiments of the present invention provide an apparatus comprising an upper transparent portion that allows light to penetrate and a lower portion coupled to the upper transparent portion. The lower portion may include a reflective concentrator that has a physical shape and reflects the light that penetrates the upper transparent portion. The apparatus may also include a feature formed in or on the reflective concentrator that is configured to modify an optical characteristic of the physical shape to be substantially similar to an optical characteristic of a desired shape.

Certain embodiment of the present invention provide a method including forming a reflective solar light concentrator having a physical shape and forming a feature in or on the reflective solar light concentrator to modify an optical characteristic of the physical shape to be substantially similar to an optical characteristic of a desired shape. The method may further include forming an upper transparent portion that allows light to penetrate and reach the reflective solar light concentrator and coupling the upper transparent portion to the reflective solar light concentrator.

Some embodiments of the present invention provide a method that includes forming an upper transparent portion that allows light to penetrate, forming a lower portion comprising a reflective concentrator that has a physical shape and that reflects the light that penetrates the transparent portion, and forming a feature in a reflective concentrator to modify optical behavior of the physical shape to match optical behavior of a desired shape. The method further includes directly embossing the feature onto a film and adding a reflective material to the film after the embossing to form the reflective concentrator. In some embodiments, the method includes adding a material to a film, embossing in the material, and adding a reflective material to the film to form the reflective concentrator. In still other embodiments, the method includes embossing in a material, forming a reflective film from the material, and adding another material to the reflective film to form the reflective concentrator. In yet another embodiment, the method further includes embossing a material to form a embossed material, adding another material to the embossed material, and forming a reflective surface using the embossed material after adding the other material to form the reflective concentrator.

Certain embodiments of the present invention provide a method that includes providing an optic element having a shape, measuring a reflectance profile of the optic element, comparing the measured reflectance profile with a desired reflectance profile, and modifying the shape of the optic element to generate a modified optic element having the desired reflectance profile.

Certain embodiments of the present invention provide a method that includes measuring the reflectance profile of the modified optic element, determining whether the reflectance profile of the modified optic element is substantially similar to the desired reflectance profile, and upon determining that the reflectance profile of the modified optic element is not substantially similar to the desired reflectance profile, further modifying the optic element.

Certain embodiments of the present invention provide a method that includes transmitting light through a transparent portion of a solar collector, reflecting the transmitted light off a first reflective film having features disposed thereon, the features configured to modify the optical properties of the first reflective film to match optical properties of a second reflective film having a desired shape, and capturing a substantial portion of the reflected light using a receiver that converts the captured reflected light into electrical energy.

Other embodiments of the present invention provide an apparatus that includes an upper transparent film, a lower non-reflective film coupled to the upper transparent film to form an inflatable structure, and one or more features located on a surface of the upper transparent film, the one or more features configured to focus incoming light onto a receiver located in an inflation space defined by the inflatable structure.

Certain embodiments of the present invention provide a method that includes forming an upper transparent film, forming a lower non-reflective film, coupling the upper transparent film to the lower non-reflective film to form an inflatable structure, and forming one or more features on a surface of the upper transparent film, the one or more features being configured to focus incoming light onto a receiver.

The following detailed description, together with the accompanying drawings will provide a better understanding of the nature and advantages of the present invention.

### BRIEF DESCRIPTION OF THE DRAWINGS

FIG. 1A shows a simplified cross-sectional view of one embodiment of an inflated solar power collector.

FIG. 1B shows a simplified cross-sectional view of another embodiment of a solar power collector.

FIG. 1C shows a simplified cross-sectional view of another embodiment of an inflated solar power collector.

FIG. 1D shows a simplified cross-sectional view of another embodiment of a solar power collector

FIG. 1E shows a simplified cross-sectional view of another embodiment of an inflated solar power collector.

FIG. 1F shows a simplified cross-sectional view of another embodiment of an inflated solar power collector.

FIG. 1G shows a simplified cross-sectional view of another embodiment of an inflated solar power collector.

FIG. 2 is a graph showing the position of a surface measured from an inflated concentrator (Hencky-type), as a function of radial distance, as well as the position of a reference parabola surface according to an embodiment of the present invention.

FIG. 3 shows two incident rays reflecting from the surfaces shown in FIG. 2.

FIG. 4 shows more rays traced from the Hencky-type surface according to an embodiment of the present invention.

FIG. 5 shows a photograph of a reflected spot emanating from an inflated concentrator according to an embodiment of the present invention.

FIG. 6A is a graph showing the calculated angular difference between an inflated primary optic and an example parabola, as a function of the radius according to an embodiment of the present invention.

FIG. 6B shows an example of an optic that, once inflated, would compensate for an inflated reflector profile to yield a concentrated light profile similar to an example parabola according to an embodiment of the present invention.

FIG. 7 is a photograph of the back of a reflective film coated with ink according to an embodiment of the present invention.

FIG. 7A illustrates a picture and irradiance profile from a reflective film without ink according to an embodiment of the present invention.

FIG. 7B illustrates a picture and irradiance profile from a reflective film with ink according to an embodiment of the present invention.

FIG. 8 illustrates a picture and irradiance profile of a reflective film spray painted with a material to improve the irradiance profile according to an embodiment of the present invention.

FIG. 9 illustrates an example of a situation where faceting is used to achieve a desired correction according to an embodiment of the present invention.

FIG. 9A illustrates a sample construction of a corrective feature useable in the example depicted in FIG. 6B.

FIG. 9B shows facets for the high slope of the balloon in both un-inflated and inflated states, in accordance with an embodiment of the present invention.

FIG. 9C shows for the low slope of the balloon in both un-inflated and inflated states, in accordance with an embodiment of the present invention.

FIG. 10A shows selected incident and reflected rays on facets on a steep section of an inflated film according to an embodiment of the present invention.

FIG. 10B shows an enlarged view of a section of FIG. 10A according to an embodiment of the present invention.

FIG. 11A illustrates an embodiment where the faceted primary optic behaves as an array of mirrors, each pointing to one of a group of cells.

FIG. 11B shows the embodiment of FIG. 11A from a different perspective.

FIG. 12 is flow diagram of a process for fabricating a reflective optic according to an embodiment of the present invention.

### DETAILED DESCRIPTION

Certain embodiments of the present invention seek to reduce the levelized cost of energy, which is the cost of generating electricity, of a solar power plant, and to maximize the scale at which such plants can be deployed. Various embodiments of power plants are described in U.S. patent application Ser. No. 12/782,932 filed on May 19, 2010, which is incorporated by reference herein for all purposes. Embodiments of solar collector devices and methods in accordance with the present invention may be utilized in conjunction with power plants having one or more of the attributes described in that patent application.

The objectives of reduced levelized cost of a solar power plant, can be achieved through the use of elements employing minimal and low-cost materials that are able to be mass produced. Potentially desirable attributes of various elements of such a solar power plant, include simple, rapid and accurate installation and assembly, ease of maintenance, robustness, favorable performance at and below certain environmental conditions such as a design wind speed, and survivability at and below a higher maximum wind speed.

According to certain embodiments of the present invention, inflation air may be used to impart a curved profile to a reflective component of a concentrator for a solar collector structure. U.S. patent application Ser. No. 11/843,531 filed on Aug. 22, 2007, which is incorporated by reference in its entirety herein for all purposes, discloses an inflatable solar concentrator balloon method and apparatus. U.S. patent application Ser. No. 13/015,339 filed Jan. 27, 2011, which is incorporated by reference in its entirety herein for all purposes, describes various configurations for inflatable balloon structures. In some embodiments, inflation air may be used to impart a liner (or trough-type) profile to the solar concentrator. U.S. Provisional Application No. 61/560,547, filed on Nov. 16, 2011, which is incorporated by reference in its entirety herein for all purposes, describes a trough-type inflatable solar concentrator. Embodiments of the present invention may share one or more characteristics in common with the apparatuses disclosed in above referenced patent applications.

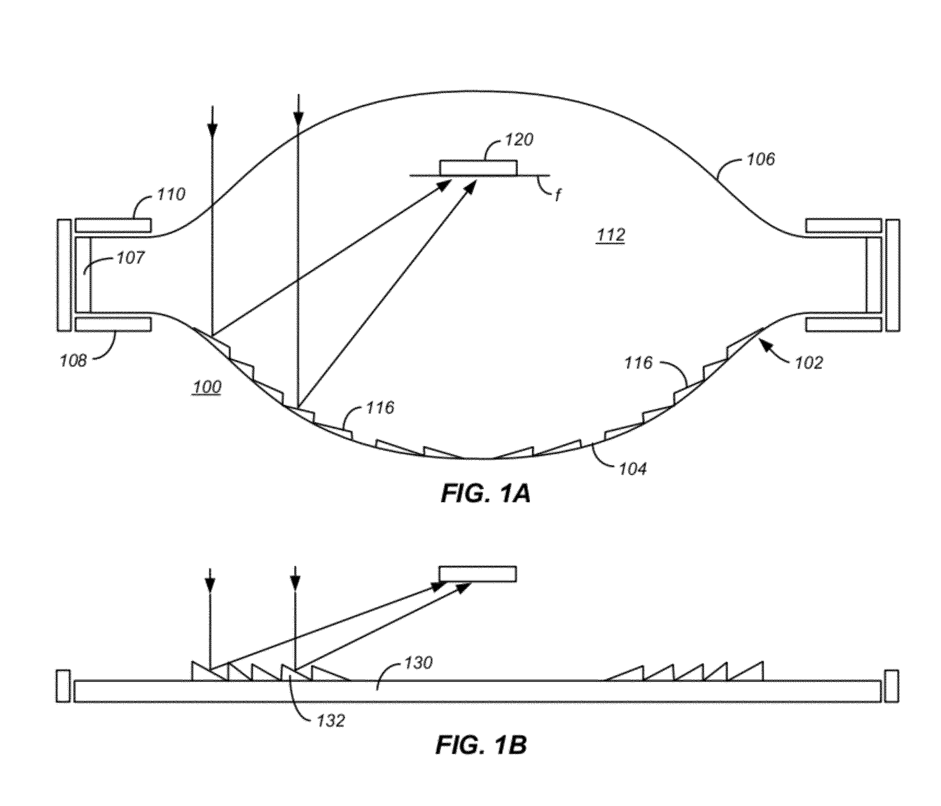

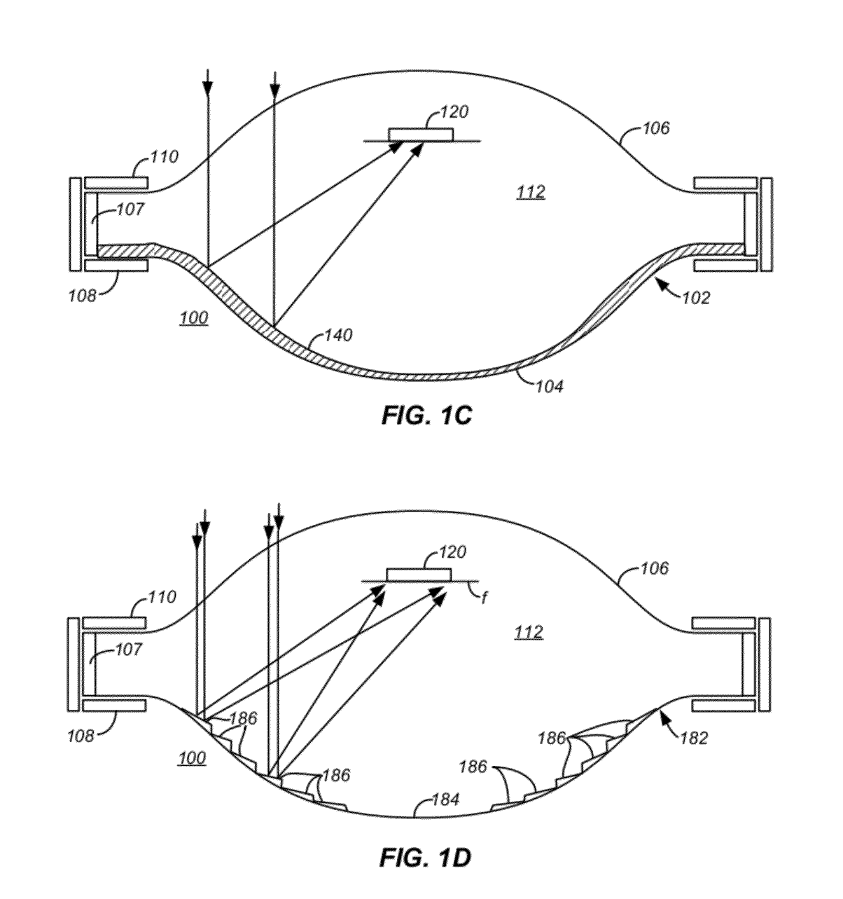

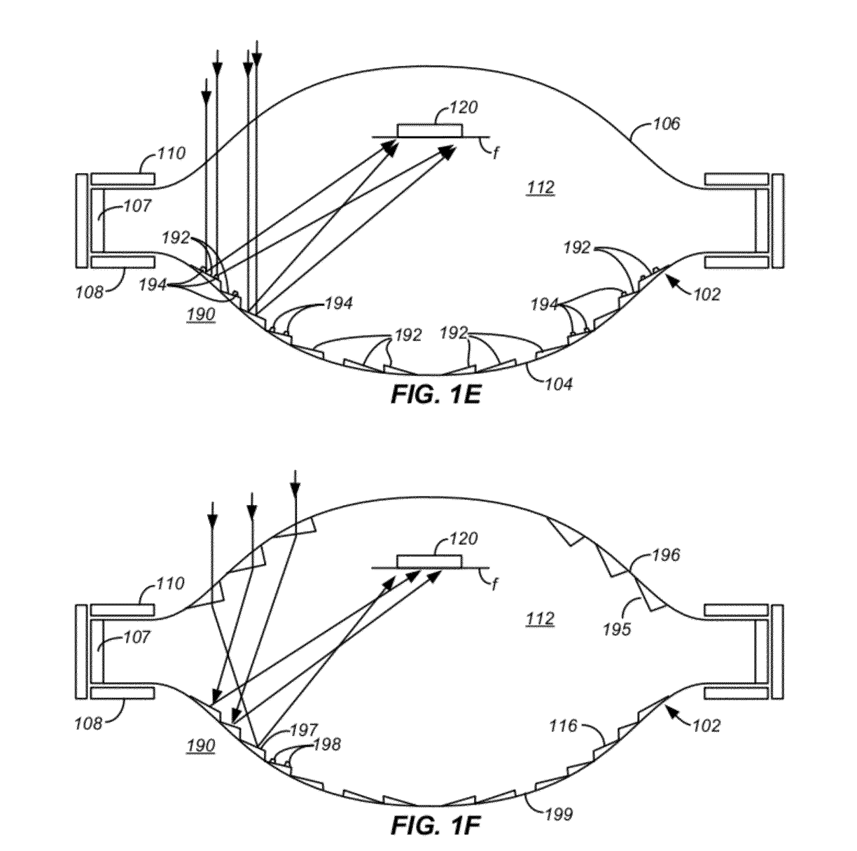

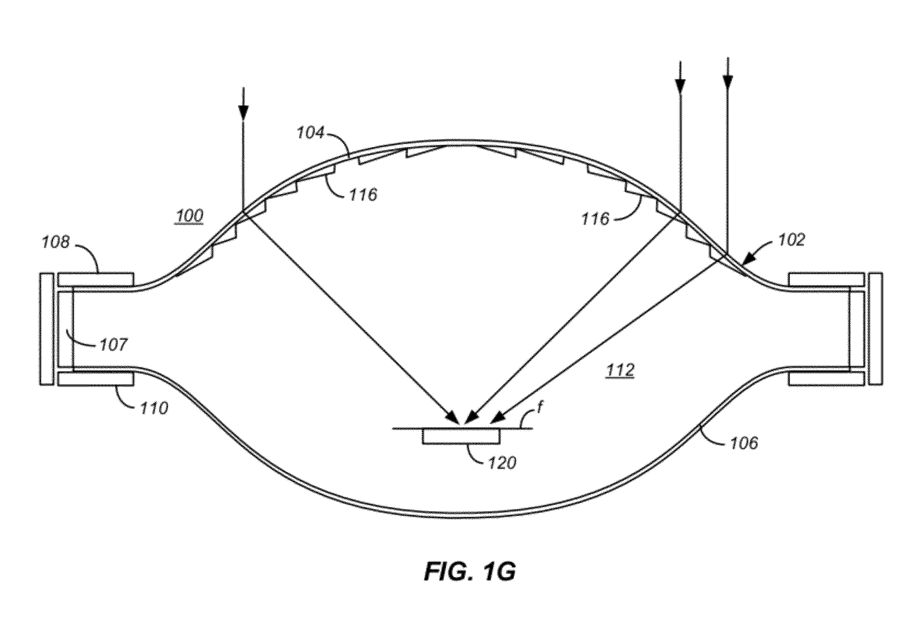

FIG. 1A shows a simplified cross-sectional view of one embodiment of an inflated solar power collector according to an embodiment of the present invention. Collector 100 comprises concentrator 102 formed by a first lower reflective film 104 sealed at its edges and a second upper transparent film 106. The films may be secured by a number of apparatuses and methods such as a harness type structure where films can be sealed to themselves, rings etc. First lower reflective film 104 and second upper transparent film 106 together form walls of inflation space 112 that can be inflated using air or other gases.

The reflective film 104 can expand into the bottom portion of a balloon shape when the inflation space 112, enclosed by the reflective film 104 and transparent film 106, is filled with gas. The film 104 can be made of aluminum, mylar, or another reflective materials. When gas is provided into the inflation space 112 between the sealed films, a balloon structure is formed.

The upper transparent film 106 may comprise a polymer. Many different types of polymers can be used to form the upper transparent film. One form of polymer which may be suitable is polyester, examples of which include but are not limited to polyethylene terephthalate (PET) and similar or derivative polyesters such as polyethylene napthalate (PEN), or polyesters made from isophthalic acid, or other diols such as but not limited to butyl, 2,2,4,4 tetramethylcyclobutyl or cyclohexane.

The transparent upper film 106 may be formed from poly(meth methacrylate) (PMMA) and co-, ter-, tetra-, or other multimonomeric polymers of methacrylates or acrylates including but not limited to monomers of ethyl, propyl and butyl acrylate and methacrylates. Other examples of polymers forming the upper transparent film include but are not limited to polycarbonate (PC), polymethylpentane (TPX), silicones, cyclic olefin derived polymers such as Cyclic olefin co-polymers (COC) and cyclic olefin polymer (COP), fluorinated polymers such as polyvinilidene fluoride and difluoride (PVF and PVDF), ethylene tetrafluoroethylene (ETFE), ethylene chlorotrifluoroethylene (ECTFE), fluorinated ethylene propylene (FEP), THV, derivatives of fluorinated polymers, fluorinated derivatives of the above polymers, and co-extruded, coated, adhered, or laminated species of the above. The thickness of the upper transparent film 106 ranges from approximately 0.012 mm to 20 mm, depending on material strength and collector diameter. In addition, the upper transparent film may be formed from one or more polymers in a film stack. The reference to films here on refers to bulk polymers made into films, films stacks, embossed polymers on films, directly embossed films and the like.

In operation of the collector of FIG. 1A, a 2-axis tracking structure may be employed to maintain alignment of the concentrator with respect to the direction of light rays from the sun. Examples of support and tracking structures used with embodiments of solar collectors are described in detail in U.S. Provisional Patent Application No. 61/299,124 filed on Jan. 28, 2010. In addition, U.S. patent application Ser. No. 11/844,877 filed on Aug. 24, 2007 describes examples of rigging systems for supporting and pointing solar concentrator arrays and U.S. patent application Ser. No. 13/015,339, filed on Jan. 27, 2011 describes some additional solar concentrator support and tracking structures. All of these patent applications are incorporated by reference herein in their entirety for all purposes. Embodiments of the present invention may share characteristics disclosed in one or more of these patent applications.

Light incident from the sun passes through the upper transparent film 106, is reflected off of the lower reflective film 104, and is accordingly focused and concentrated on a receiver 120. In the embodiment of FIG. 1A, the receiver 120 is positioned at or proximate to a plane ‘f’ that is at a working distance corresponding to the desired focal ratio.

The receiver 120 is configured to convert the reflected and concentrated solar energy into other form(s) of energy. According to some embodiments, the receiver may comprise a photovoltaic (PV) structure that is configured to convert solar energy into electrical energy. Such a PV receiver may be cooled using water, glycol, air, or combination thereof.

In certain embodiments, the receiver 120 may comprise a concentrated solar power (CSP) structure that is configured to convert solar energy into thermal energy through a working fluid having desirable properties. For example, the working fluid may be input to a heat engine such as Sterling engine or micro-turbine. Such working fluids can include air, nitrogen, helium, hydrogen, water, molten salts or oils.

U.S. patent application Ser. No. 11/844,888 filed on Aug. 24, 2007, which is incorporated by reference herein in its entirety for all purposes, discloses photovoltaic or thermal receivers for cost-effective solar energy conversion of concentrated light. U.S. patent application Ser. No. 11/843,549 filed on Aug. 22, 2007, which is also incorporated by reference herein for all purposes, discloses interconnection systems for solar energy modules and ancillary equipment, including fluid conduits to a receiver.

The shape of an inflated lower reflective film 104 may result in an irregular illumination profile on the receiver. This irregular illumination profile can in turn reduce the efficiency of the solar receiver and the overall efficiency of the system. In addition, the irregular illumination profile restricts the maximum concentration achievable by the system.

Thus according to embodiments of the present invention, the lower reflective film 104, which serves as an inflated primary mirror, may include features 116 that are configured to globally correct the optical behavior of the concentrator. In particular, the features 116 are designed to correct the reflective profile of the surface of the lower reflective film 104, to a desired shape (for example in some embodiments a parabolic shape).

In some embodiments, the features 116 may be impressions that can be formed by embossing. Such embossing may be of a film directly, or may be of material added to a film prior to or after a reflective structure is created or a reflective material is added. For example, the impressions can be formed directly on a film to which the reflective material is added to form reflective film 104 or can be formed on substrate onto which the reflective material is added and then attached to a film thus forming the reflective film 104. In one application, the features 116 are designed such that the difference in slope of the actual inflated surface of reflective film 104 and that of a desired surface is compensated for. The difference between achieved and desired slope, for example, is illustrated in FIG. 6A. Hence, the slope of the facets would represent a distribution similar to that of FIG. 6A. Since the slope of features 116 is defined by the difference between the slope of the inflated surface of reflective film 104 and the slope of the desired surface, and the thickness of features 116 is determined from the thickness of the reflective film 104 or applied material and/or the speed of processing, then the width of the facet is then calculated. For example, as illustrated in FIG. 6A, for an approximately 3 meter diameter reflective film, the difference between the desired and achieved slop is approximately 2 degrees at 1.5 m radius. At this point, if the depth of the embossed structure is 40 μm, then the width of the facet would be approximately 1150 μm. A more detailed description of the calculation is given below in connection with FIGS. 8-12.

In embodiments where the perimeter of the reflective film 104 is circular in shape, corrective features 116, may be annular shaped and may be used to achieve the global correction. The annularly shaped corrective features follow the shape of the circular perimeter. In embodiments where the perimeter of the reflective film 104 is other than circular, e.g., linear, corrective features that continuously follow the outline of the film can be used to achieve the global correction.

While FIG. 1A depicts a collector comprising a receiver positioned within an inflation space, embodiments of the present invention are not limited to this particular configuration. Alternative embodiments could employ different designs and remain within the scope of the present invention. For example, U.S. Provisional Patent Application No. 61/381,842 filed Sep. 10, 2010, which discloses a solar collector having a receiver positioned external to an inflation space, is incorporated by reference in its entirety herein. Embodiments of the present invention may share one or more characteristics in common with the apparatuses disclosed in that patent application.

While FIG. 1A depicts a circular inflatable concentrator for point focus, embodiments of the present invention are not limited concentrators having this shape. Alternative embodiments of concentrators could have other shapes and still remain within the scope of the present invention. For example, some other embodiments of an inflated concentrator may include a linear concentrator for line focus, often referred to as a trough. Optical features formed by embossing or other techniques as disclosed herein could be used to provide correction of the illumination profile yielded by such a trough structure.

In some embodiments, the concentrator may include an inflated structure having a substantially lenticular shape (which may result in a focal point lying outside of the inflation space). Again, optical features formed according to embodiments of the present invention could provide for correction of the illumination profile of such a concentrator structure.

In some embodiments, the front (transparent) surface of an inflatable concentrator can be substantially planar while the reflective film 104 may be curved, for example where the front film 106 has sufficient thickness to impart rigidity that resists bowing in response to the internal inflation pressure. Optical features according to embodiments of the present invention can also be used to correct the illumination profile provided by such a structure.

In some embodiments, the correction features 116 can also be used to correct the illumination profile of other alternate concentrator shapes. Examples of such alternative concentrator shapes include spherical-shaped, or pillow-shaped for square or rectangular balloons, or linear concentrators.

Moreover, while FIG. 1A depicts an inflatable concentrator, embodiments of the present invention are not limited to such inflatable structures. Alternative embodiments according to the present invention could comprise other than inflated structures. One alternative example is illustrated in FIG. 1B which shows a collector including a substantially planar reflective concentrator structure 130 that comprises a plurality of features 132. This type of reflector may be substantially planar or may be used anywhere a low shape fidelity optic is used and the optic in FIG. 1B can correct the irradiance profile from the low shape fidelity optic to appear as an optic with acceptable irradiance profile.

FIG. 1C illustrates still another example where the reflective film 140 of the concentrator exhibits a varying thickness profile. Such a thickness profile can be achieved in the lower reflective surface through the use of embossing and can inflate to a more desired shape via the varying mechanical properties in the film. In one example, the mechanical properties, e.g., thickness, of the reflective film 140 varies such that when the concentrator is inflated, the inner surface of the reflective film 140 facing the receiver forms a substantially parabolic surface when inflated. In a particular embodiment, the reflective film 140 can be thinnest at the center and may get progressively thicker from the center to the edges of the reflective film 104. The reflective film 140 in this embodiment can be made by embossing or by forming a non reflective layer whose thickness varies as described and then depositing a substantially uniformly thick reflective coating over the non-reflective layer, or using a uniformly thick reflective material and depositing a non-uniform material on the back surface of the non-reflective layer such that the film inflates to the correct profile

Returning to FIG. 1A, the non-uniformity of illumination that is to be corrected by features according to embodiments, may result from the specific shape assumed by an inflated film, which is often referred to as a “Hencky surface.”

A secondary optical structure can also be used to compensate for the non-uniform nature of the primary reflectance. U.S. patent application Ser. No. 12/720,429 filed on Mar. 9, 2010, which is incorporated for reference herein in its entirety, describes optical structures including secondary optics. Embodiments of apparatuses according to the present invention may share one or more aspects in common with this patent application. However, secondary optical structures may require complex optics such as total internal reflectance (TIR) structures, adding expense. In addition, the increased range of angles of rays reflected from inflated structures makes optical secondary designs utilizing TIR more challenging.

It is desirable to correct any inefficiencies in the primary optic, e.g., reflective layer 104, to ensure uniform illumination of the receiver 120. This makes the entire system more robust and less vulnerable to tracking errors. This is especially true given that such correction of illumination uniformity according to the present invention can be employed in conjunction with passive compensation in the receiver and/or correction in a secondary optic, in order to enhance collection efficiency.

According to one embodiment, a typical primary concentrator profile is a parabolic reflector that causes reflected rays to converge at a single point, and causes regions near the focus to exhibit a high degree of uniformity. However, since (a) a parabola does not create a perfectly uniform profile outside of its focal point, (b) the sun is not a perfect point source, and (c) tracking error considerations may drive a reflective shape that differs from a parabola, modifications to a parabolic reflector are made in some embodiments. For example, the desired primary concentrator profile can be a faceted reflector. In a faceted reflector, the reflector comprises an array of reflectors that can individually direct light to a same place, with superposition from the individual reflector facets.

According to certain embodiments, a primary optic element that is larger than a single facet may be used. A primary optic element that is larger than a single facet may be desirable for one or more reasons. One reason is that a large primary optic allows certain components to be amortized over a smaller number of receivers. For example, inflating one large primary optic would require less supporting equipment versus multiple small primary optics that may each require a set of supporting equipment, e.g., wires, hoses, and a multitude of tracking motors or actuators, wheels, cooling systems, etc. In addition, some support structures may not scale linearly with the area of the optic, though the solar collection will so that the average support structure mass may be minimized by a larger primary optic. Further, a large primary optic can make maintenance easier. In some embodiments, a single, large primary optic can simplify alignment of the optic and maintenance.

Solar structures may trade off the efficient use of land, which would prefer higher packing density of structures. Higher packing density, however, can cause problems with one concentrator shading another. Shading may cause problems with production of electricity if the photovoltaic receiver is shaded non-uniformly. Shading issues, however, can indicate in favor of low aerial density of structures. For an imaging primary optic (such as a parabolic primary) the phenomenon of one balloon shading another increases illumination non-uniformity on the receiver. A non-uniformly illuminated receiver may non-linearly drop in electrical output because the photovoltaic elements may be connected in a string, or limit the operating range of a thermal receiver due to non-uniform heat distribution. Due to the superposition of the individual elements, a receiver collecting light from a faceted reflector will lose energy proportional to shading, but will substantially maintain uniformity in the illuminated region. Hence, a faceted primary optic can yield better land use or better overall system efficiency, in addition to the other possible advantages yielded by primaries that are substantially larger than a single facet, as described above. In addition, facetted primaries can normalize out individual reflector abnormalities or imperfections also improving the uniformity on the receiver.

According to embodiments, the optical performance of an inflated film may be corrected to a parabolic or other shape reflector behavior, and/or may be corrected to faceted reflector behavior. Some embodiments may relate to such correction in CPV systems where solar energy is converted into electric power. Other embodiments may relate to correction in CSP systems where solar energy is converted into heat energy.

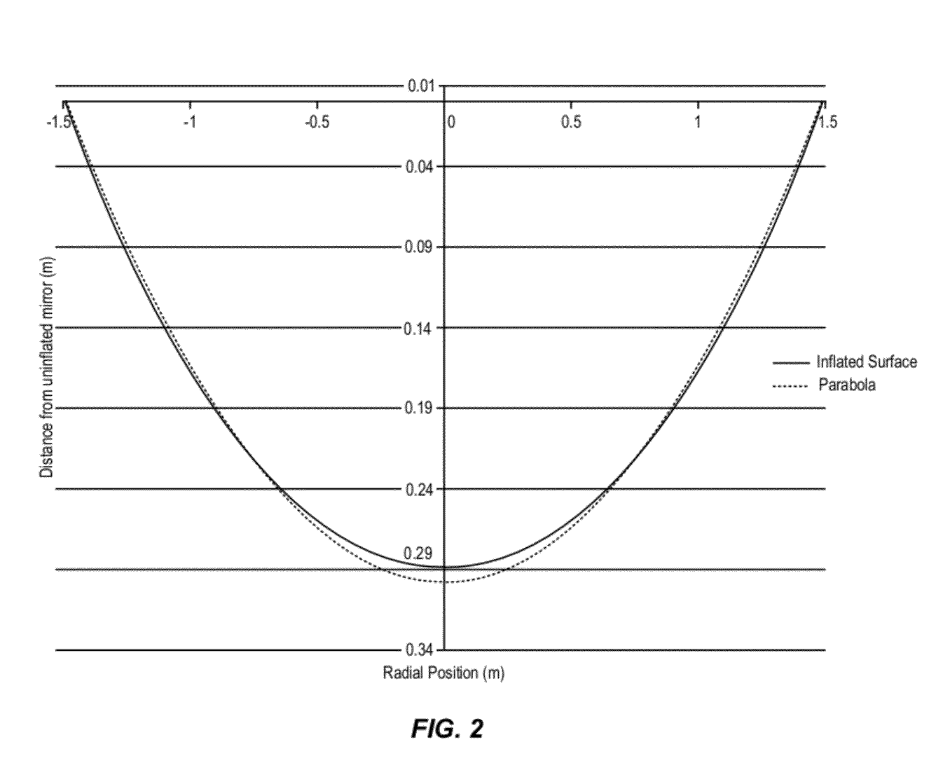

FIG. 2 plots on the same graph the position of a Hencky surface (solid line) assumed by an inflated concentrator and the position of a corresponding parabola (broken line). In particular, the surface of the inflated concentrator is determined as follows. A light source with varying x, y position is generated. Light therefrom is reflected from the inflated film onto a camera which allows the position of the reflected ray to be known.

From the known, varying light source and known position of the reflected ray, a least squares routine can be used to iterate for position of the mirror. A polynomial is then fitted to satisfy the entire surface of the mirror. The following table 1 shows exemplary radially symmetric polynomial coefficients for an inflated primary mirror of radius 1.4859 m:

TABLE 1

| Polynomial Coefficient | Value |
|---|---|
| R⁰ | −0.289059 |
| R² | 0.117972 |
| R⁴ | 0.002308 |
| R⁶ | 0.002403 |
| R⁸ | −0.001053 |
| R¹⁰ | 0.000314 |

As illustrated in FIG. 2, a plot is generated for the surface defined by these polynomials. The y=0 axis represents the uninflated position of the film. The solid line represents the inflated concentrator profile, which illuminates a 0.3 meters in diameter circle at 1.397 meters from the y=0 axis, hereafter referred to as the “spot”. A corresponding receiver could be positioned at this location. In this example, a parabola is used as an example of the desired shape. The parabola may be generated as follows.

Since the edge of the balloon is fixed, the example parabola shape has the same clamped outer ring position as that of the inflated structure. That is, the inflated and desired curves share the points (−1.4859, 0) and (+1.4859, 0). A parabola fitting these points is chosen, for which the outer diameter of the parabola images onto the outside diameter of the spot utilized for the inflated structure. That is, the parabola is chosen such that it provides the same diameter spot. Thus, in FIG. 2, the dashed (broken) line represents a parabola that satisfies the boundary condition of (−1.4859, 0) and also the condition that the reflected ray from point (−1.4859,0) impinges at the edge of the receiver, the point (−0.15, 1.397). Geometry describes that parabola, and the shape is drawn in FIG. 2 as the parabola that would illuminate the spot formed by the inflated structure.

FIG. 2 shows that with respect to the example parabola, the inflated structure exhibits lower displacements near the center of the structure, and exhibits higher displacements near the edge. This generates a higher slope than desired as the radii is increased. Hence, in the inflated structure, the higher slope at the edge reflects light towards the center of the spot instead of the edge of the spot. As a result, a receiver placed at the spot location may get substantially non-uniform illumination. In addition, in this instance, an element on the receiver may now receive light from different locations from the primary optic, making refractive secondary optics difficult. Also, further inflation of the primary optic to decrease the radius of the spot may not be possible since the rays emanating from the inflated primary optic may miss the receiver. Whereas a smaller receiver may be beneficial to keep the cost of the photovoltaic elements down, in some instances the inflated structure may not allow for a smaller receiver.

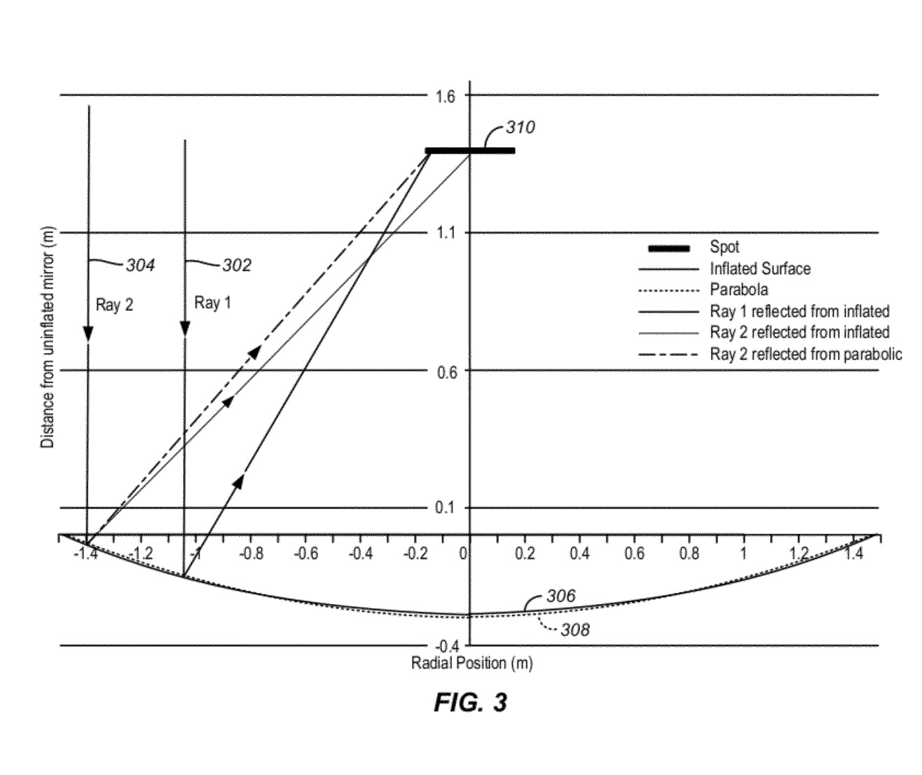

FIG. 3 shows two incident rays 302, 304 reflecting from the surfaces (Hencky 306, parabolic 308) shown in FIG. 2. The first ray 302 is reflected off of the inflated curve at about x=−1.05, and is incident at the edge of the simulated spot 310 despite not emanating from the edge of the primary optic. The second ray 304 incident at x=−1.4 is reflected off of the inflated curve (solid), and is imaged toward the middle of the spot of a simulated receiver. This is unlike the parabaloid situation, where the ray incident at x=−1.4 is reflected (dashed line) to image near the edge of the spot of the simulated receiver.

The inflated concentrator thus has a greater slope at the far reaches of the radius, as compared with the example parabola. This causes the reflected rays to cross, resulting in non-uniform illumination of the receiver and restricting the maximum concentration allowed by the system.

In FIG. 3, the two incident ray traces are shown with calculated reflections as well as the “spot” at 1.397 meters, which is 0.3 meters in diameter. The interior trace at x=−1.05 m shows only the reflection from the inflated structure. As shown in FIG. 3, the reflection ends up near the edge of the spot despite the fact that it emanates at about ⅔ of the radius. The second incident ray 304 is near the edge of the primary optic at x=−1.4 m. In this case, the reflected ray from the inflated structure actually comes back into the receiver area. The density of rays is higher near the edge of the spot, and then fold back into the spot. This creates a bright ring around the edge of the spot, a result of the non-uniform illumination.

In addition, the incident angles of the rays reflected from the inflated (solid) surface are more varied than the angles of rays reflected from the parabolic (dashed) surface. For example, the reflected ray from the example parabola, which is also shown at x=−1.40 for reference, lands near the edge of the spot.

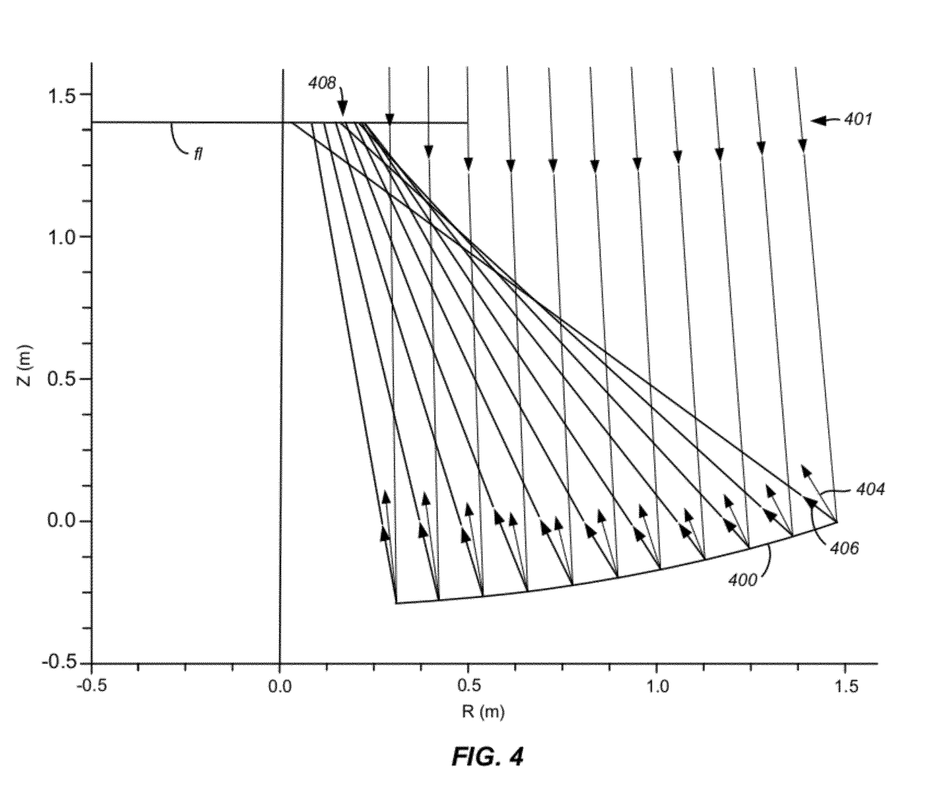

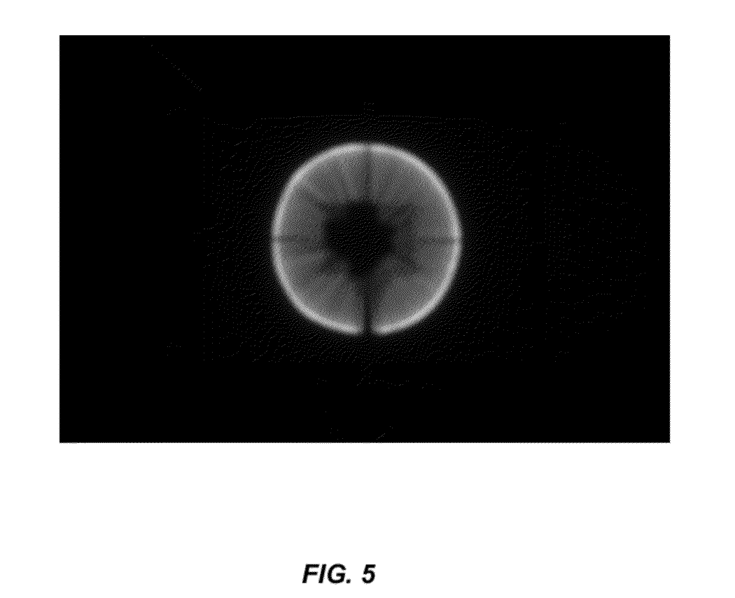

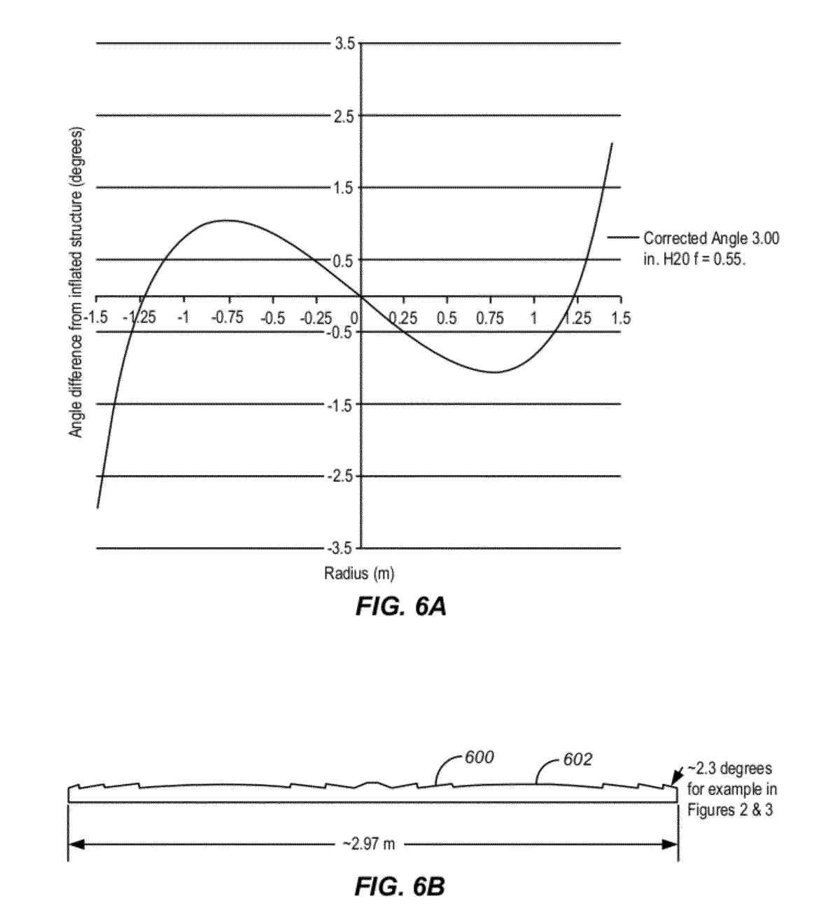

FIG. 4 shows more rays traced from inflated, Hencky-type surface 400. Multiple incident rays 401 are modeled, with surface normal rays 404 and reflected rays 406. Reflected rays 406 are incident on a spot 408. The illumination intensity is greater on the outer edge of the spot 408, a result of the inflated structure. The spot 408 is not uniformly illuminated, largely because the Hencky-type surface 400 has slopes that are too high near the edge. Thus light reflected from about ⅔ of the radius of the primary reflector, crosses back over itself on the spot 408, leaving a bright ring around the edge.

An image associated with such a situation is shown in FIG. 5. FIG. 5 is a photograph of reflected spot emanating from an inflated concentrator. The bright ring at the edge of the spot is due to the imperfect primary reflector and its inflated construction.

FIG. 6A shows the calculated difference in slope between an inflated primary optic, and a parabola, as a function of the radius. This plot can be used to generate the profile of an optic to compensate for this difference in slopes. The angular difference at a particular radii is shown, and this is the designed angle of a substantially annular or faceting feature after inflation. Hence, the incident light in this instance will experience a reflection similar to that which would be experienced by a parabola or desired shape. For example, the angle of the feature 116 in FIG. 1A can be determined by this method.

In particular, FIG. 6B shows an example of an optic 600 that is designed to compensate for an inflated reflector profile. FIG. 6B shows an under-formed film that upon deformation in response to inflation pressure would correct the reflectance profile to generate an image appearing to be one from a parabola.

To design such an optic, a profile of a typical inflated structure is measured. In certain embodiments, this profile may be measured utilizing proprietary hardware and software as described above in connection with varying light source and known position of a reflected ray, followed by iteration for position of the mirror. The resulting output is a point by point mapping of a typical inflated concentrator under specific sealing conditions. Examples of such conditions include but are not limited to, the pressure within the inflation space of the balloon, fastening conditions, and structure design.

The difference between the mapped points, and points of the desired shape, e.g., a parabola, is then calculated as shown in FIG. 2 and more broadly in FIG. 3. The slope error, in angles can then be calculated as shown in FIG. 6A. As an example, at a distance of approximately 1.4 meter of radius from the center of the reflector, the angular correction needed is about 2.3 degrees. Thus, at the distance of 1.4 meter, a feature is designed to be mostly planar with a slope of 2.3 degrees. If an embossing process is used such that 20 μm of material is added and an embossed depth of 15 μm is used, then from the angle desired (2.3 degrees) and the depth of emboss (15 μm), the width of the feature can be calculated. A second example is that at a distance of approximately 1.23 m, no angular correction may be needed, and for radii of less than 1.23 m, an angular correction in the opposite direction may be needed, until at the center, no angular correction is needed again. The slope correction is a matter of sign convention. For example, in FIG. 6A, the slope needed to correct the optic at −1.4 m from the center is depicted as a negative slope change. The slope change is symmetric about the origin, but may be subject to convention. In addition, FIG. 6A illustrates that the slope correction for −1.4 m is not identical in magnitude as the change at +1.4 m. This may be due to experimental conditions such as ring roundness, fastening conditions at the edge, film mechanical property non-uniformities, metrology errors and the like. A typical process for iterating to the correct slope changes is described below.

In certain embodiments that include a circular balloon, a globally-corrective feature includes an annular shape having a curved surface. This is shown, for example in feature 602 of FIG. 6B the top of the feature could be slightly curved to substantially mimic the final desired curvature upon inflation.

In some embodiments, the globally-corrective feature may comprise an annular shape with a flat section that is small in width as compared to the primary optic. For example an annular shape could be 1 mm wide, while the optic is 1.4859 m in radii. The edges of the annular shape could be determined by the allowable error from the assumption of a flat annular shape. This error is estimated to be small for example, on a 1 mm wide annular shape.

According to some embodiments, the thickness of the reflective film itself could be modified. Such modification in the reflective film thickness could be achieved spatially by embossing. For example, if a particular thickness profile is determined to inflate to a desired physical shape (e.g. a parabola) then the embossed structure could simply be used to add thickness to some areas of the film and not to others. An example of such an embodiment is shown in FIG. 1C. In such a process, the shape needed to correct for the inflated profile would first be hypothesized. For example, one physical reason for the Hencky shape may be attributable to the fixed ring/harness condition at the perimeter of the balloon, where the fixed harness provides constraint in the circumferential direction.

Using a fixed harness at the edge is less restraining to the radial film strains at the edge than the situation at the apex, where strains occur in both directions. As such, the radial expansion of the balloon near the circumference is higher than near the apex. Hence one may emboss or otherwise alter the film at the edge such that the force needed to radially strain the film at the edge compensates for the fixed ring condition which otherwise preferences radially strains at the edge during expansion.

Initially, the theoretical calculations may be presumed to be correct, and that there is a quadratic thickness variation from center to edge. A film could then be embossed to this shape. The film would be utilized in a balloon structure and then the reflectance of the film can be measured in the manner indicated above. In some embodiments, a picture such as illustrated in FIG. 5 can be taken to substantiate the enhanced irradiance distribution to verify the actual inflation shape to the desired accuracy. Successive iterations can then be used, if needed, to alter the inflated structure to achieve the desired shape.

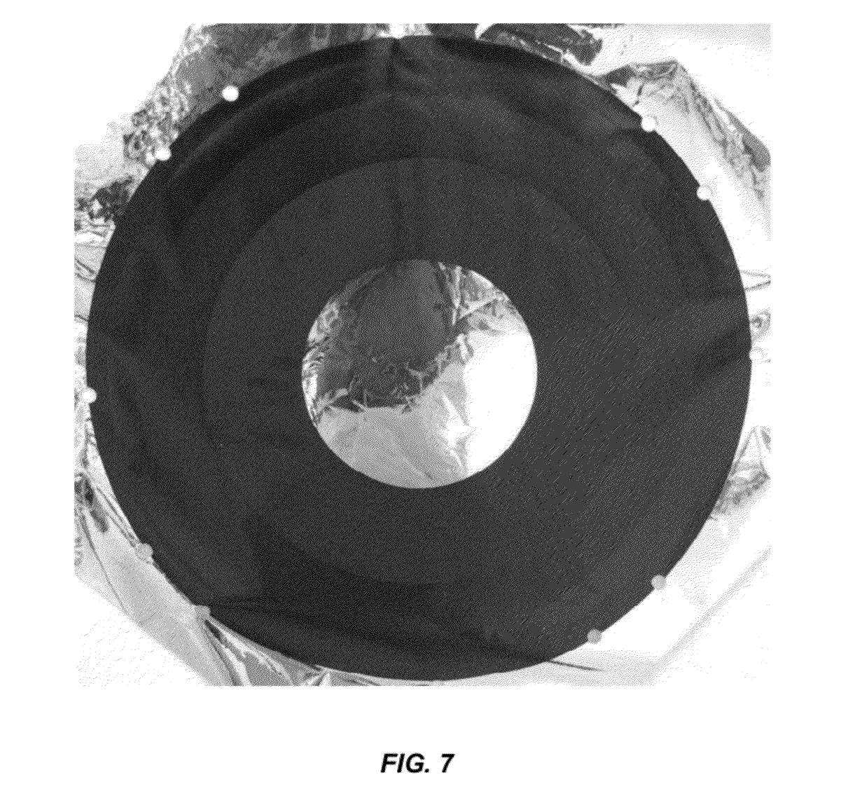

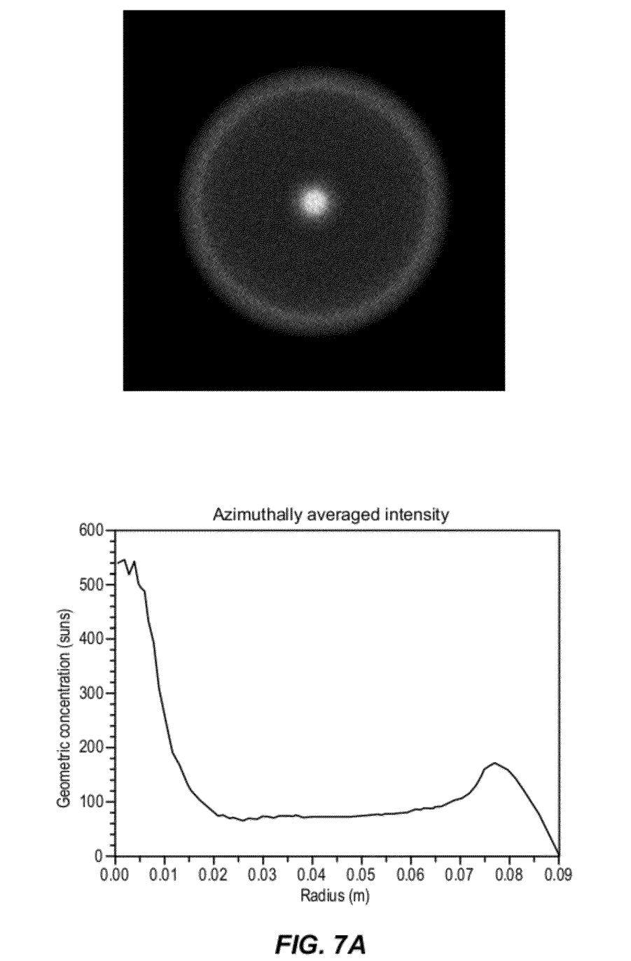

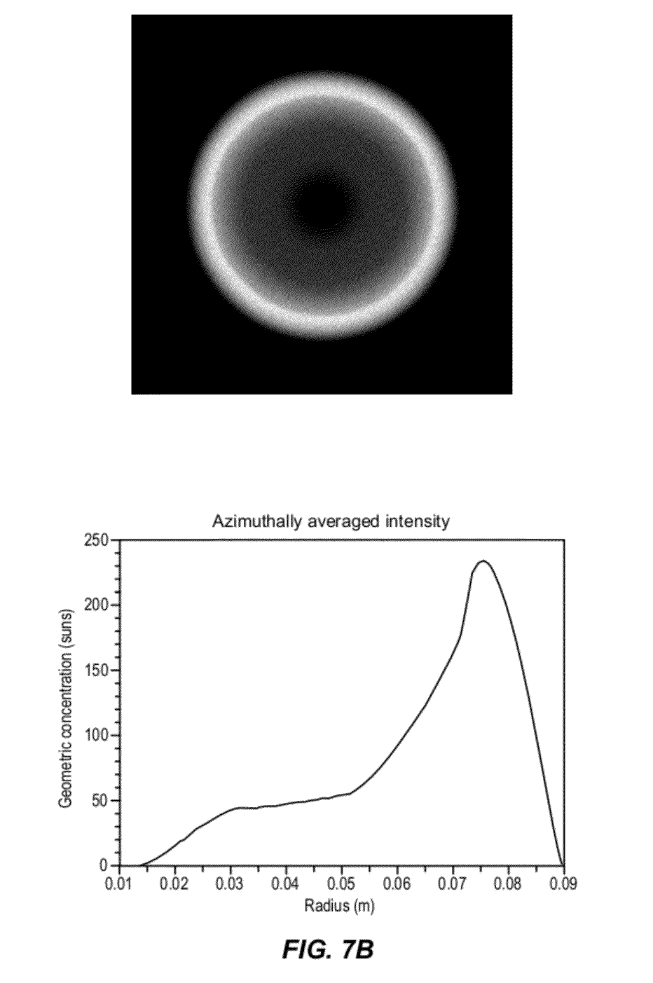

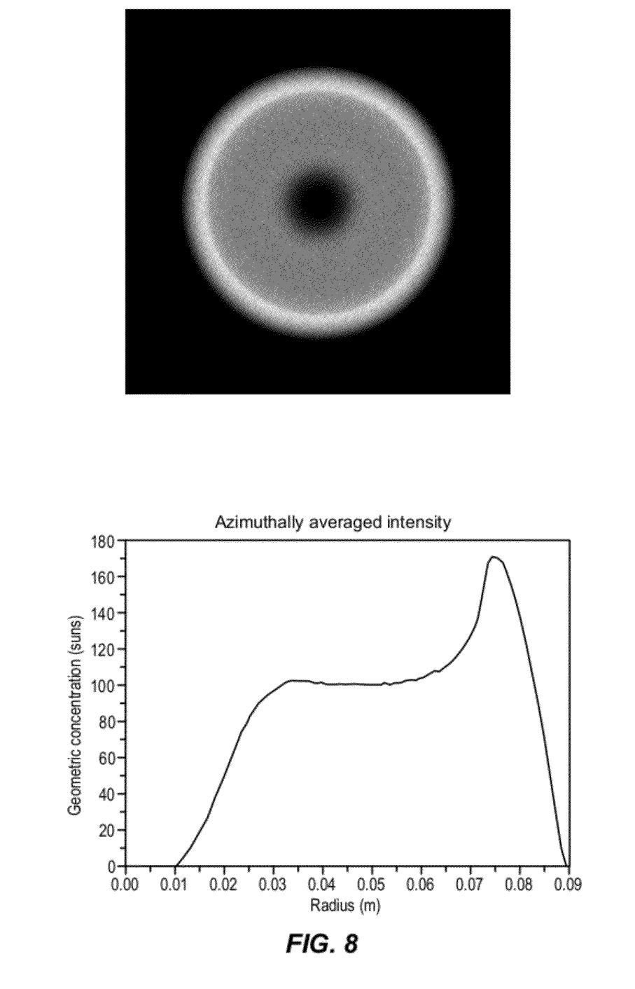

One other embodiment of enhancing the irradiance profile as in FIG. 1C is to vary the thickness profile of the film via film application techniques such as screen printing. As an example, a screen ink such as Nazdar ink ADE52 with ADE677 catalyst was applied to the film such that it increased the modulus of the film approximately linearly with thickness of the applied ink. In some embodiments, the ink can be applied in 4 successive screen prints such that there is an increasing modulus of the mirror as it approaches the edge. In this instance, 18 in. diameter balloons were used and the film from this balloon after it was removed is shown as in FIG. 7. The ink goes to just past the boundary at which the film was held. FIG. 7A illustrates the picture (top) and irradiance profile (bottom) from a film without ink. FIG. 7B illustrates the picture (top) and irradiance profile (bottom) of the film with ink as shown in FIG. 7. It is to be noted that the irradiance profile of the typical Hencky film in FIG. 7A casts light from the edge of the film to the center of the spot as well as has the bright ring as described before. This may result in limiting the achieved system concentration as the increased concentration may result in even higher slopes at the edge of the primary optic, and result in the light missing the receiver. In FIG. 7B, there is a more direct correlation between the light reflecting from the optic to the radial position on the receiver, showing that the most light (coming from the outer edges of the primary) is cast substantially upon the outer edges of the receiver. So while this film is not completely a parabola, it will suffice for greater than 350× optical concentration when a typical film without ink is restricted to approximately 70× concentration without losses.

In another embodiment a paint of the appropriate modulus can be spray-painted onto the reflector film. In this example, a clear-coat urethane paint was sprayed onto a 6 foot diameter film using a stationary spray gun and rotating table. The paint showed a substantially linear increase in overall modulus of the film plus coating vs. the thickness of the coating. From this, a first film was sprayed. FIG. 8 shows the picture and irradiance profile obtained for this film. There is improvement from the virgin film which showed a profile similar to the 18 in. virgin film shown in FIG. 7A. As shown below, an iterative procedure is used to determine the amount spray needed to generate a desired spot.

While it is shown that various materials can be applied to the film to alter the point focus irradiance profile at the receiver plane by use of screen printing or paint spraying, it is clear that similar techniques can be used to achieve a more optimal line profile and that other techniques to increase the strength of the film spatially are equally beneficial.

Returning to embossing options, the type of optic shown in FIG. 6B may be fabricated using embossing or other such technique in a roll-to-roll manner. Specifically, in certain embodiments the desired annular shape or overall film thickness variation may be created as follows.

A mold master is first formed. In some embodiments this mold master can be a hard electrodeposited alloy formed from a photoresist or other mold. The mold master could alternatively be formed by directly machining the mold onto the roller that is to be used. Once a master stencil is made, submasters may then typically be fabricated from the master and included on the roll apparatus. In certain embodiments, a corrective feature is formed from additional material present on the surface of the film. Thus in some fabrication processes, the film is coated with a material that is easier to emboss.

For example, in certain embodiments a polymer is first added onto the film, and then the polymer is embossed. The film with coating can be run through rollers for example as described above, and the relief from the submaster is embossed into the added coating. The polymer coating including the corrective feature can then be cured by exposure to UV radiation, for example. A reflective component (such as a thin layer of Al or another metal) can then be added to the embossed coating in order to produce the reflective structure.

It may also be possible to emboss a polymer film directly, such that the facet may be formed as a shape in the material itself. Thus according to some embodiments, the embossing stamp is utilized to impress directly into the film material into a desired corrective shape (e.g. rounded or faceted) at a temperature. A thin metal (such as Al or Ag) may then be applied/deposited over the relief structures to produce the reflective structure.

According to still other embodiments, embossing may be performed directly into a reflective material to form the optical features. The process of embossing may typically be performed near or proximate to the glass transition temperature of the polymer or thermoplastic with subsequent slow temperature decrease. However, methods which use additional curing steps may perform the shape change on substantially oligomeric species or other liquidus materials at low or near room temperature, and bring the polymer Tg or other mechanical properties up by subsequent UV or other curing step.

According to still other embodiments, a material may be embossed directly but then added to an otherwise structural film by use of an adhesive or thermal lamination techniques. The thin reflective material may be added before or after embossing or before or after the joining of the embossed material with the structural film.

While the above description has focused upon forming features by embossing, the present invention is not limited to using this particular technique. Alternative embodiments could employ other approaches to form the desired optical features.

For example, one alternative approach is the use of a thermoform technique. In the thermoform technique, a mold is created for which the polymer and or mold is heated and pressed onto the mold via vacuum. The mold shape could exhibit the negative of the corresponding feature that is desired to be formed. In some embodiments, only the active or reflective surface of the film retains a substantially modified shape. In other embodiments, both the active surface of the film and the opposite or rear surface of the film may change shape due to the forming process. If both surfaces are allowed to change shape, facets or features much larger than the thickness of the film may be created.

Still other approaches are possible. For example, the optical features according to embodiments of the present invention could be created by techniques such as laser ablation, stencil printing, or other direct write techniques such as inkjet printing. Various approaches that can add or subtract material locally could be used to form the optical features according to embodiments.

As described in detail below in connection with FIG. 1F, still other embodiments may utilize embossing or other techniques that add or subtract material locally to the front transparent film. Optical features formed in such a manner could act alone as a refractive optical element, or in concert with features on the back reflective film, to achieve the desired enhanced illumination profile.

Embossed features of the primary optic can be fabricated up to pure 90 degree retroreflectors, if necessary. As shown in the FIG. 1, the embossed corrections are typically steps in cross-section. However it should be noted that features of other shapes may also possibly be used, for example to improve reflectivity or to increase the transmission of the front film for the solar concentrator.

Embodiments may work with square balloons or balloons having other shapes, for example to achieve a higher packing density of collectors. In such embodiments, the receiver could also take on a different shape. A reflective primary optic according to embodiments of the present invention could further include features configured to implement other corrections of the image. Such effects include but are not limited to explicitly minimizing an effect of tracking error, avoiding certain receiver regions, or creating other illumination patterns as desired.

Returning to the embodiment of FIG. 6A, at x=−1.4 m the slope difference between the rays reflected from an inflated structure and from a parabolic structure may be about 2.8 degrees. This slope difference gets smaller at lower radii, comes to zero at about 1.23 m, and then reverses for smaller radii. This is representative of the embodiment shown in FIG. 6B. Such a corrective optic structure can be used at a variety of inflation profiles or spot sizes, though different embossed geometries could be used for different spots and different reduction ratios.

It is to be noted that the present invention is not limited to correction to a parabola, but rather to correcting to whatever structure is desired. For example, the general spot irradiance profile for a parabolic reflector is a truncated Gaussian profile. Different shapes can be corrected using commercial optical design software, such as FRED from Photon Engineering of Tucson, Ariz., or ZEMAX from Zemax Corp. of Bellevue, Wash.

In some cases a profile is designed using as a standard asphere of the form:

z(r)=(r²/(R(1+SQRT(1−(1+k)r²/R²))))+a₁r²+a₂r⁴+a₃r⁶+a₄r⁸ . . .

This profile deviates from a parabola in such a way that the spot has a uniform distribution, rather than a Gaussian distribution. This would be a special case of an optimized asphere, and an asphere optimized specifically for uniform irradiance in a reflected spot. In other embodiments, the asphere may be optimized for tracking error tolerance, or minimizing receiver cell area for example.

Once the optimized aspheric shape is determined, the piecewise deviation between the shape of the inflated film (the Hencky surface) and the optimized asphere can be determined. The deviation can be determined by performing a point to point subtraction between the optimized asphere and the measured shape of the inflated film. Alternatively, the deviation can be determined by fitting the optimized asphere and the measured shaped of the inflated film to mathematical functions (one function for each), such as n^{th} degree polynomials, and then subtracting the two mathematical functions to obtain a third mathematical function, which represents the deviation. The compliment to this deviation could be embossed piecewise into the plastic film.

Since both shapes (the Hencky surface and the optimized asphere) are axis-symmetric forms, the shape of the embossing would likewise be axis-symmetric. The shapes could take the form of concentric circles, where each annular area has a wedge shaped embossed feature to yield the desired ray angle at the design inflation pressure and corresponding shape.

In addition, the invention is not limited to achieving correction through the use of imprinted or embossed features alone. According to some embodiments, such correction may be implemented in conjunction with corrections applied to the front film by embossing or other techniques, and/or secondary optics, and/or other passive compensation schemes.

Certain embodiments may also achieve correction of non-uniform illumination through local changes to the physical shape of the reflecting surface itself. Some embodiments, which adopt such an approach, involve the formation of facets. FIG. 1D shows a simplified view of such an embodiment of an inflated solar power collector in accordance with the present invention. As with the embodiment of FIG. 1A, the collector comprises concentrator 182 formed by a first lower reflective film 184 having a concave profile.

The embodiment of FIG. 1D includes certain local features that change its optical characteristic. In particular, the reflective film 184 includes selectively positioned local facet features 186. Such faceted features on the reflective film 184 (i.e. the primary optic) reflect from a more local area to cover the entire receiver, rather than the entire reflective film 184 being utilized to illuminate the receiver. Thus, the spot at the receiver plane is a superposition of the reflectance from many facets. In a particular embodiment, the reflective film 184 may be altered such that it appears to be a “facetted” primary optic to the receiver.

In such embodiments, portions of the primary optic can uniformly illuminate the receiver, and the receiver illumination profile would therefore be a superposition of multiple facets. In this way the result of shading would be a loss in efficiency proportional to the shade area subtended, though the illumination uniformity on the receiver is not affected.

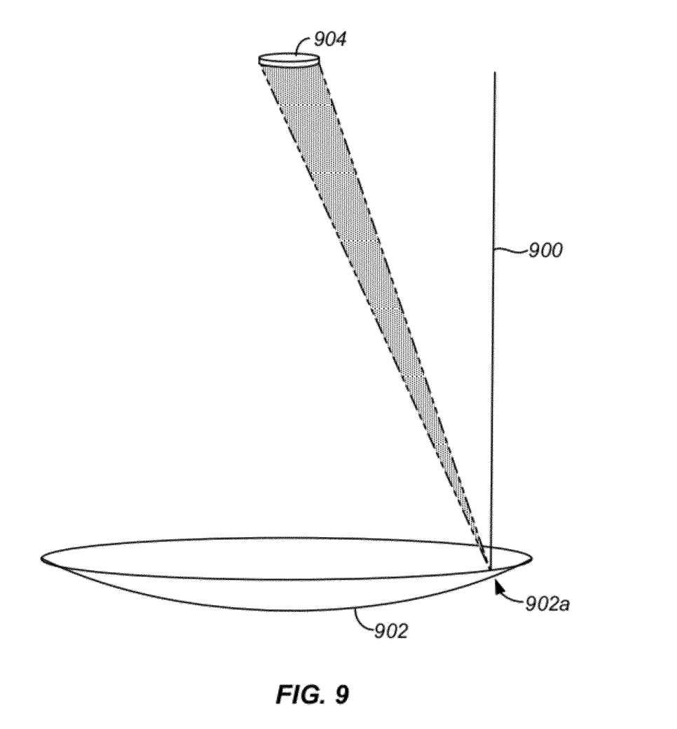

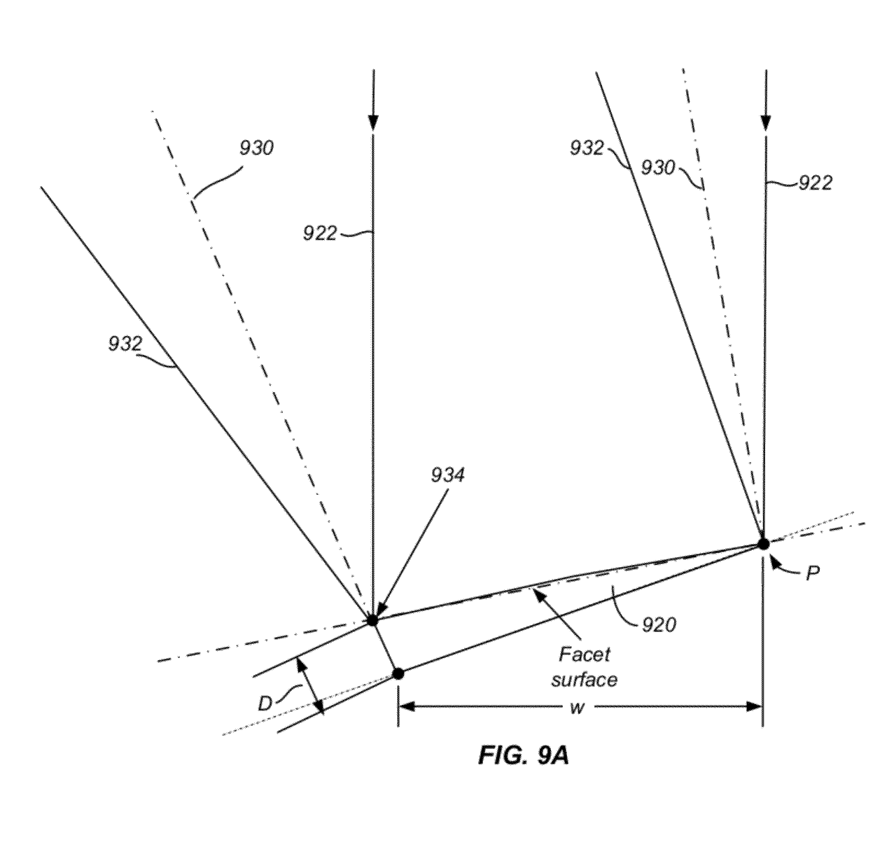

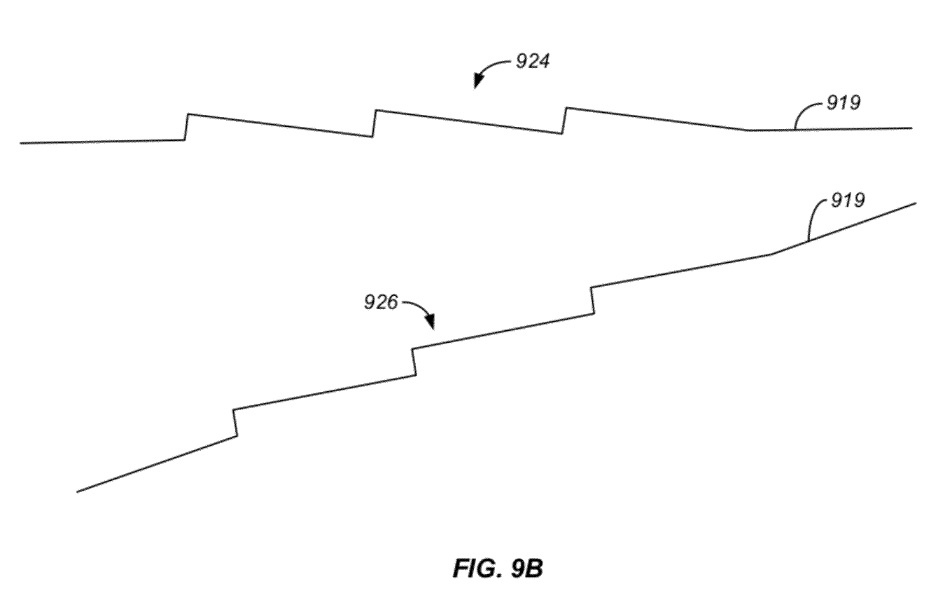

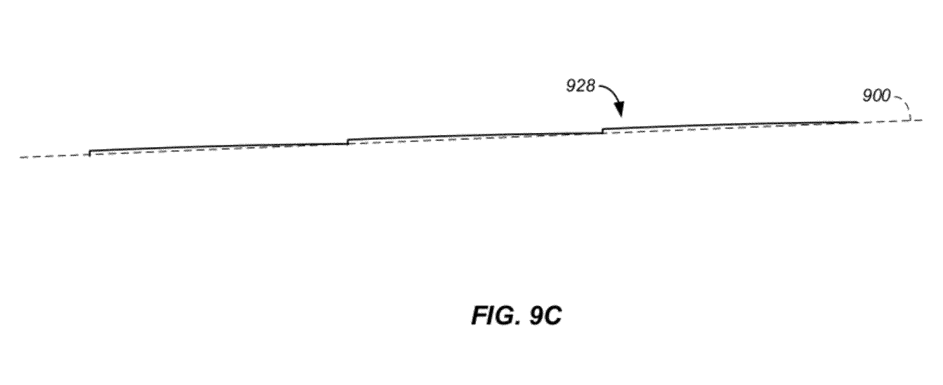

In one embodiment, a planar facet may uniformly illuminate the receiver. In this instance, the facet could be 0.3 meter diameter size. However, embodiments of the present invention are not limited to this, and facets may be any shape that tessellates or can be tiled to cover the inflated film. Facet size and surface curvature may also be chosen in a variety of ways. Facets may be much smaller than the receiver and still uniformly distribute light over the receiver surface as shown in FIG. 9.

Moreover, the receiver may be any shape. A surface may be designed for a shaped facet in order to distribute its reflected light evenly over a receiver of any shape. Thus the receiver shape could be a hexagon or other tessellating polygon or sets of polygons.

Facets may be planar or non-planar. In general, for a facet to evenly distribute light over a receiver, it may be non-planar. However there may be cases where planar facets are desirable, for example because of manufacturing reasons or because or specific schemes of light concentration.

FIG. 9 again shows the use of faceting to achieve desired correction according to an embodiment. Light 900 impinging on a small section 902a of the primary optic 902 is reflected to illuminate the receiver 904 uniformly. By superposing multiple reflected spots from the primary optic 902 onto the same receiver area, partial shading of the primary optic 902 results in a nearly uniform decrease in light on the receiver 904 as opposed to highly non-uniform receiver shading created when a continuously curved primary surface is partially shaded.

In FIG. 9, light 900 impinging on a small section of the primary optic 902 illuminates the entire receiver area. As an example, one can facet the primary optic 902 to include many facets, each of which may illuminate the receiver. Under partial shading conditions, the receiver 904 may end up with a uniform decrease in intensity which allows for high efficiency from the receiver.

FIG. 9A illustrates a close-up view of an embossed reflective facet 920. Facet 920 is created such that the incident rays 922 at either side of the facet 920 reflect about surface normal 930 to create reflected rays 932 which are directed to corresponding opposite sides of the receiver (not shown). Other rays (not shown) that may strike facet 920 somewhere in between the extreme edges may be reflected so that they hit the receiver at a corresponding location in between the edges of the receiver. For a certain embossed depth D (for example, 0.0003 inches) of facet 920 to be applied at one facet edge such as location 934, the difference between the desired slope of the facet edges, and the nominal film surface slope, and a point “P” on the facet that is not affected by the embossing, one can calculate the length or width W of the facet (here 0.0020 inches). The slope at each edge of the facet (here locations 934 and P) can be chosen so that light rays hitting those facet edges will be reflected to corresponding sides of the receiver. If the surfaces at the facet edges are connected with a smooth surface, the slope of which changes smoothly from edge to edge without any inflection points, all the light hitting the facet will be reflected to the receiver if the incident light is from a collimated source. When many such facets are used in conjunction, the net pattern of light hitting the receiver can be made to be more uniform than if the primary optic surface was smooth. The net light at the receiver can also be more uniform under conditions where a portion of the primary optic is shaded.

Mapping of light rays to a desired distribution at the receiver requires a slight arc or other shape to connect the required surface slopes at each end of the facet. If the facet is smaller than the receiver, the facet surface will be convex if it is continuous. Since embossed depths may typically be between several microns and 100 microns (and typically between 5-50 microns), the depth of the embossing and the desired angular correction sets the length of the facet in this design. Facets can be the longest possible, such that losses due to imperfect molds at the edges of the facet are minimized. The radii of curvature plus a wavelength of light may be lost at the corners.

FIGS. 9B-9C show typical facets for the high slope and low slopes of the balloon according to an embodiment of the present invention. In particular, FIG. 9B shows an embossed film 919. In one instance the embossed film may include facets 924 that have a flat shape when un-inflated and thus a lower slope. In other instances, the embossed film may include facets 926 that have a higher slope in an inflated condition. FIG. 9C shows the same film 919 that is inflated but with facet 928 in the low slope regime.

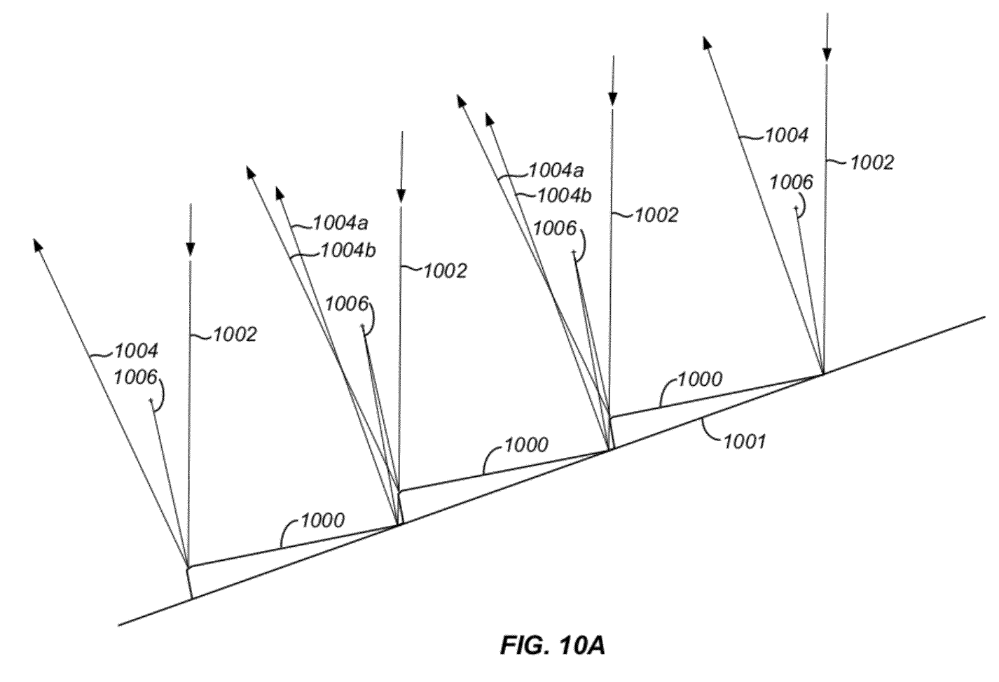

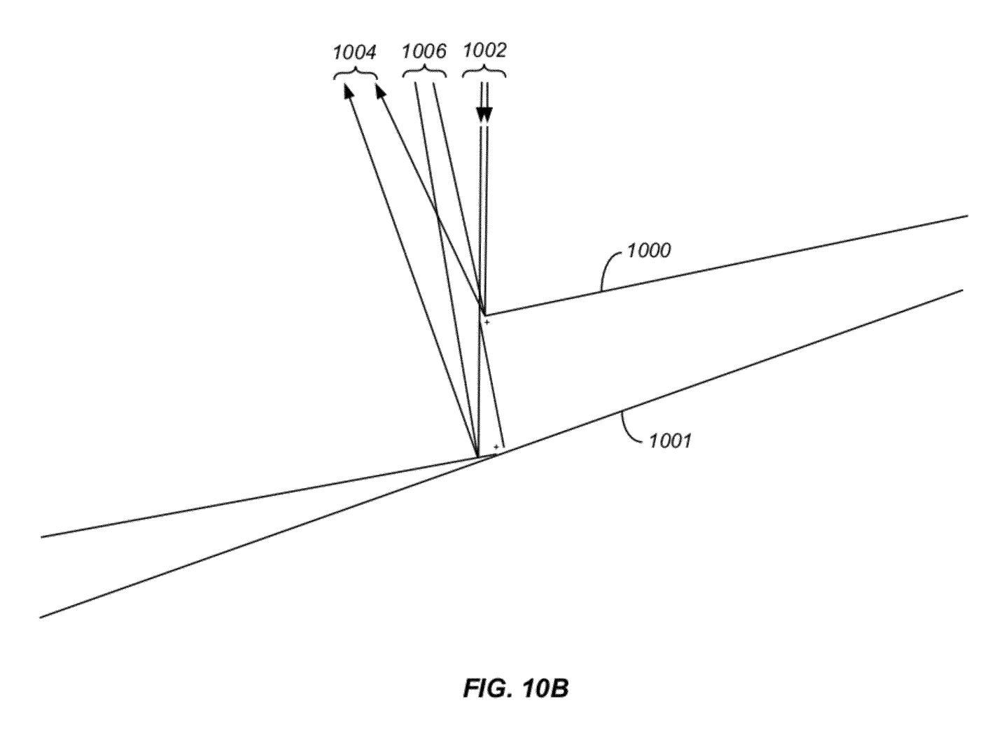

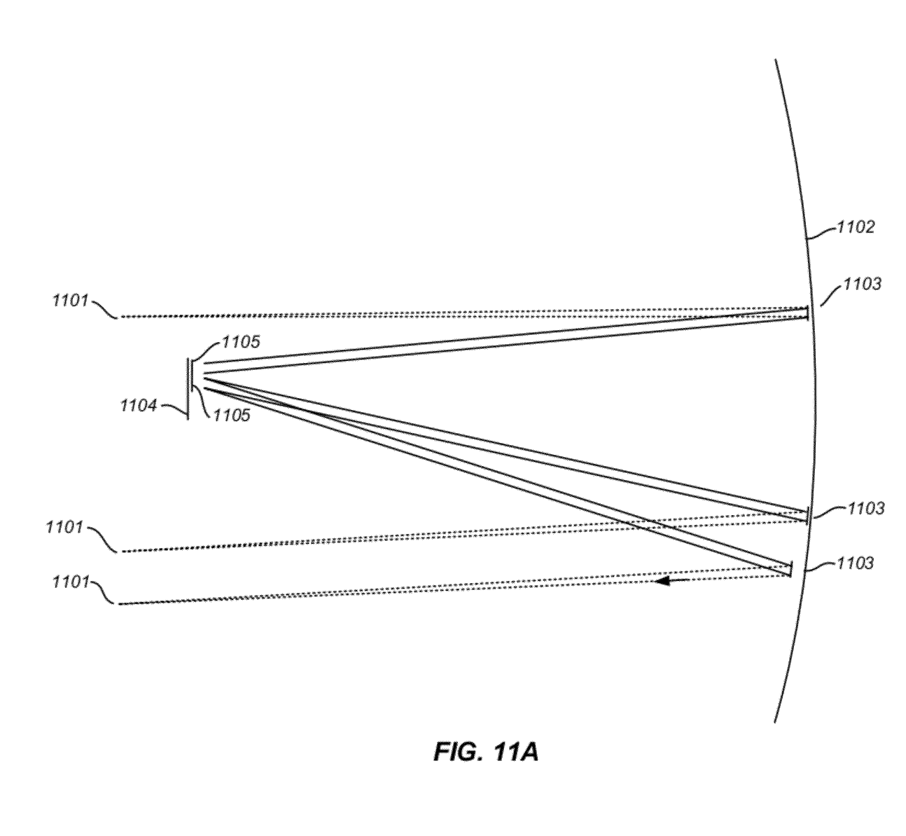

FIG. 10A shows selected incident and reflected rays on facets 1000 on a steep section of an inflated film 1001 according to an embodiment of the present invention. In particular, incident rays are labeled as 1002, reflected rays are labeled as 1004, and the surface normal of the facet at the point of incidence for each ray is shown as 1006.

In FIG. 10A, the rays 1004a, 1004b are reflected from either end of the step between facets 1000 and cross one another. This is because the reflected ray at the left side of a facet goes to the left side of the receiver, and the reflected ray at right side of a facet goes to the right side of the receiver.

FIG. 10B shows an enlarged view of a section of FIG. 10A. A reflective surface 1001 has one or more facets 1000. Two parallel rays 1002 are shown as incident on either end of the step between two adjacent facets 1000 and surface normal 1006 are shown. Note that the reflected rays 1004 go in different directions because they go to different sides of the receiver.

Rays within the radius of curvature of the embossed features, and rays likely within a wavelength of the edge, may be lost to reflection. Specifically, light impinging the corners of the facets 1000 will not reflect to the receiver, either through diffraction or because of the radii of curvature from the embossing mold. Hence, some loss is expected. With long enough facets, however, this loss would be small. For example, for the high slope regime which requires the highest angle of correction, and hence narrowest facet width and an emboss depth of 20 μm, that the facet length would be approximately 125 μm.

For example, with a 1 μm corner radii plus an average wavelength of 0.8 μm, the approximated loss regime would be about 1.3 μm on either side of the 125 μm length, or about 2%. In other words, reflected light from incoming light incident in a location that is approximately 1.3 μm from either end of a facet will be lost and will not impinge on the receiver. In case of shallow slope regimes and the same embossed depth as above, the facet width would be about 1152 μm, resulting in a loss of approximately 0.2%.

A variety of facets can be created based on the information disclosed above. First, the facets could be wider than the examples described above thus minimizing the percentage loss at the edge of the facets. In certain embodiments, the facetted surface could have its own curvature. Second, the facets may illuminate only a portion of the receiver. This can maximize efficiency by avoiding illumination of non-receptive areas between individual solar cells. Third, the facets could illuminate only a portion of the receiver, but be combined with more facets such that the receiver is uniformly illuminated. For example, in an embodiment one hundred facets would each add to uniformly illuminate the receiver, but multiple hundreds of facets may be present on the primary optic or reflective film.

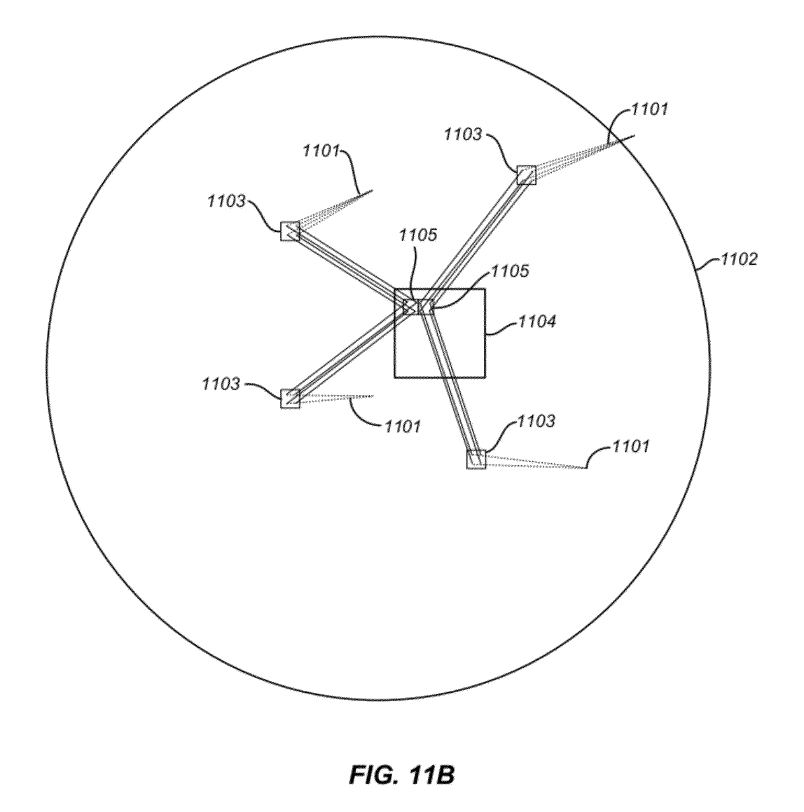

An embodiment of such as system is shown in FIG. 11A. Incoming rays 1101 strike primary optical surface 1102 with embossed features 1103. Each embossed feature 1103 is located such that reflected rays from each of the embossed feature 1103 is directed toward one of the several areas 1105 on receiver surface 1104. In certain embodiments, each of the areas 1105 correspond to the active area of a photocell. FIG. 11B shows the same system from a perspective behind the primary surface 1102. In this view, the embossed features 1103 are square features acting as a plane mirror and direct incoming rays 1101 toward one or more of a plurality of corresponding areas 1105 on receiver surface 1104. Corresponding areas 1105 are each illuminated by rays reflecting from a plurality of embossed features 1103. The ratio of embossed features 1103 to illuminated areas 1105 yields the geometric concentration ratio of the system.

According to certain embodiments, the illuminated areas 1105 may correspond to the active areas of photovoltaic cells, and the un-illuminated interstitial areas between illuminated areas 1105 may correspond to non-photoelectrically active areas, for example contact areas, solder areas, printed wire traces, etc. By directing light away from these non-active areas, the efficiency of the system can be increased. Superimposing the plurality of light rays reflected from facet features 1103 on areas 1105 can achieve a high degree of uniformity along with a reduction in non-uniformity attributable to partial shading. While the embossed features 1103 and the corresponding illuminated areas 1105 are shown as square in FIG. 11B, techniques according to embodiments of the present invention can be extended to rectangular, triangular, hexagonal, or any other tessellating or tiling geometry.

Under certain conditions, the system may be partially occluded (as by clouds or by systems on adjacent trackers at the extremes of sun position in the sky). In this situation, rather than certain cells being occluded or partially occluded, the intensity on each cell would stay substantially uniform but decrease with increasing occlusion. In this way, the system becomes more tolerant of both tracking errors and occlusion. This allows the stiffness, accuracy and cost of the tracking system to be optimized for greater total allowable error.

This configuration also makes the system more tolerant to partial shading (occlusion). Such greater occlusion tolerance allows systems to be packed more closely together on a given portion of land potentially reducing an overall cost of power even as some systems partially occlude other systems at certain times, such as in the morning, evening, and near the winter solstice or being able to utilize a larger array of potential sites for a given utility maximum power requirement.

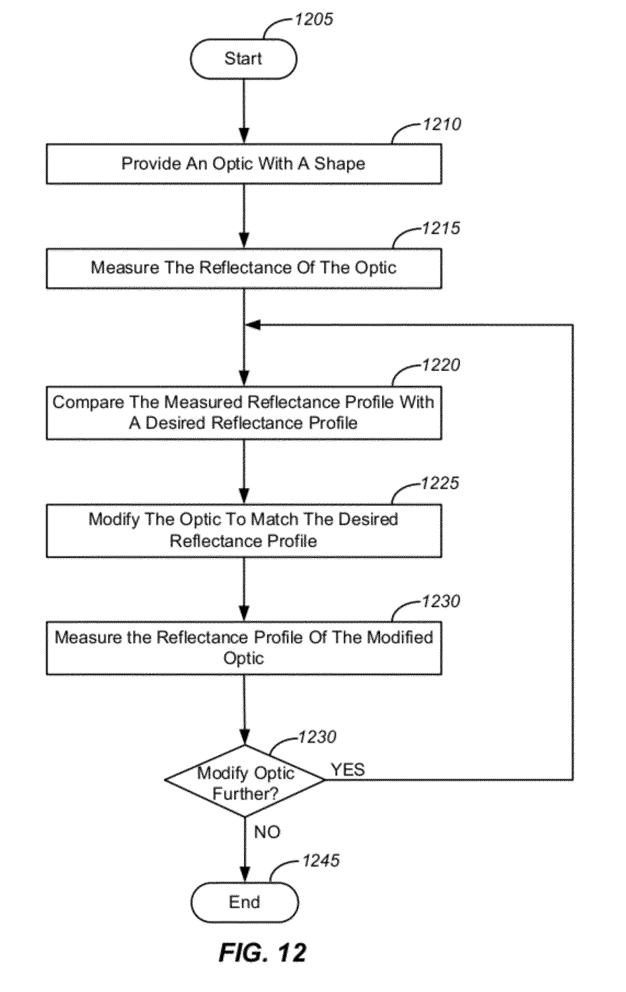

FIG. 12 is a flowchart illustrating a method of fabricating the corrective optic element used in the solar collector. The method begins in operation 1205 where initialization operations are performed to start the process. The initialization operations can include turning on equipment, calibrating equipment etc. In operation 1210, an optic (i.e. optic element) having a shape is provided. The shape of the provided optic element can be a Hencky shape when used as an inflated optic. Next in operation 1215, the reflectance profile of the provided optic element is measured. The reflectance profile can be measured using various techniques such as those described with reference to the proceeding figures. In operation 1220, the measured illumination profile on the receiver is compared with a desired reflectance profile. In one embodiment, the desired illumination profile is reflected from a primary optic. The desired profile can be an asphere, which is selected by a user. In some embodiments, the desired reflectance profile is a parabolic or near parabolic profile. The comparison between the measured reflectance profile and the desired reflectance profile can be done using techniques such as a least square fit technique, as well as other techniques as described with reference to the proceeding figures.

Next in operation 1225 the optic element is modified to match the desired illumination profile. The optic element can be modified by changing the thickness profile of the optic element, by fabricating features on the optic element, by fabricating refractive features of the front film, or by doing all of the above. The thickness profile of the optic element can be modified by changing the thickness of the optic, for example, as described with reference to FIG. 1C. The optic element can also be modified by fabricating features on the optic element as described with reference to FIGS. 1A-1G. After the optic element has been modified, the reflectance profile of the modified optic element is measured again and checked in operation 1230. The illumination profile can be measured in the same or similar way as it was previously measured. Next in operation 1230 a decision is made whether the modified optic element should be further modified. This decision is based on the illumination profile of the modified optic element. In some embodiments, a threshold value is set and if the measured illumination profile of the modified optic element is sufficiently close to the desired illumination profile and meets this threshold value, then the modified optic element is considered satisfactory and no more modification are needed. However, if the measured illumination profile falls short of the threshold value, then the optic element is not considered satisfactory and is modified again. If the decision in operation 1230 is that optic element does not need to be further modified (i.e. meets a threshold value), then the process continues to operation 1245 where the process ends. If the decision in operation 1230 is that optic element needs to be further modified (i.e. does not meets a threshold value), then the process continues back to operation 1220 where the measured illumination is compared with a desired illumination profile to determine how much additional modification is needed. This iterative process continues until an acceptable (i.e. meets a threshold value) optic element is fabricated. The method ends in operation 1245, when the final optic element is fabricated.

It should be appreciated that the specific steps illustrated in FIG. 12 provide a particular method of fabricating an optic element according to an embodiment of the present invention. Other sequences of steps may also be performed according to alternative embodiments. For example, alternative embodiments of the present invention may perform the steps outlined above in a different order. Moreover, the individual steps illustrated in FIG. 12 may include multiple sub-steps that may be performed in various sequences as appropriate to the individual step. Furthermore, additional steps may be added or removed depending on the particular applications. One of ordinary skill in the art would recognize many variations, modifications, and alternatives.

While the above figures illustrate the formation of global and local corrective features in separate embodiments, the present invention is not limited to this. According to alternative embodiments, features may be formed to achieve both global and local correction in one structure and on both front transmissive and/or back reflective films.

An example of such an embodiment is shown in FIG. 1E. Specifically, this inflatable concentrator structure 190 includes a first set of features 192 that are designed to modify the Hencky surface to parabolic in nature. The inflatable concentrator structure 190 also includes a second set of faceted features 194 that are designed to allow a local portion of the concentrator to illuminate the entire receiver. A similar embodiment could be achieved with a first global correction done with film thickness variation as shown in FIG. 1C, and a second set of features provides local correction (e.g. for example to achieve the reflection of a facetted primary) in conjunction with the global correction.

As noted above, corrective optics according to embodiments of the present invention may eliminate the need for a secondary optic. This in turn may relieve the system of a restriction whereby rays from the primary incident on the receiver, must be within an acceptance angle range of the secondary optic. In optical terms, this is the “speed” of the system also known as the focal ratio. Relieved of this restriction, it is possible to decrease the focal ratio of the system. This increases the range of angles incident on the receiver, which may then be limited by the acceptance angle of the PV cells. Since the PV cells typically have a greater acceptance angle than secondary optics, this allows the system to be made much shorter for given power. That is, the system may operate at a lower focal ratio (i.e. F/0.4 instead of F/0.8).

Such a reduction in focal ratio may provide performance advantages for the solar concentrator system. For example, the lateral displacements of the light spot(s) may be reduced for a given tracking error. In addition the system may be shorter in height overall. Such reduced structure size consumes less materials, results in less wind loading, less weight, and ultimately lower cost through direct savings in the concentrator system and indirect savings in the support system.

In addition to forming inflated concentrators, embossed features according to embodiments of the present invention may be employed for any optical system in which the cost of manufacturing a substrate having a desired physical shape exceeds the cost of locally deforming the film to achieve the illumination profile of that physical shape.

For example, certain embodiments may involve the formation of embossed corrective features on an upper transparent film of an inflatable concentrator structure, as illustrated in FIGS. 1F and 1G. FIG. 1F illustrates an inflatable concentrator having additional embossed features 195 on the transparent film 196 in addition to the first set of embossed features 197 and the second set of embossed features 198 disposed on the lower concave reflective film 199. These features can be formed by embossing or other techniques, and may act in concert with the back film or alone to achieve the desired correction of the illumination profile. Such features may serve to correct the illumination profile of a lower reflective inflated film exhibiting a Hencky-type surface to a reflectance associated with parabolic or other asphere shape.

Certain embodiments may involve the formation of embossed corrective features on an upper transparent film of an inflatable concentrator without a reflective back surface, as illustrated in FIG. 1G. FIG. 1G shows incident rays primarily focusing by refraction onto a receiver 120. Embossed features 116 are located on the upper transparent film 104. The embossed features 116 refract the light to a point or line focus and help in correction of the shape of the inflated structure.

In addition to performing optical compensation, embodiments having embossed features on an upper transparent film may offer other potential benefits. One possible advantage is a reduction in optical losses via increased transmission from structures similar to moths' eyes and hence improved performance of the entire collector device.

An anti-reflective component could serve to reduce reflection of incident light by the upper (transparent) component of the concentrator. The reduced reflection would allow the collection of light that would otherwise be lost to reflection, thereby improving the performance of the device.

For example, the use of an anti-reflective component in an upper transparent portion of a collector, could reduce expected optical losses from around 5.5% per surface (total 11% single pass, 22% double pass) to around 1% per surface (total 2% single pass, 4% double pass) in an embodiment comprising an embossed moth's eye anti-reflection coating on an optically transparent material. In addition, embossed components on the upper surface may produce increased resistance to soiling and super-hydrophobic behavior.

Although specific embodiments of the invention have been described, various modifications, alterations, alternative constructions, and equivalents are also encompassed within the scope of the invention. The described invention is not restricted to operation within certain specific embodiments, but is free to operate within other embodiments and configurations, as it should be apparent to those skilled in the art that the scope of the present invention is not limited to the described series of transactions and steps.

It is understood that material types provided herein are for illustrative purposes only. Accordingly, reflective films can be made of various different reflective materials such as materials comprising polyethylene terephthalate (PET), as described in some embodiments herein. Similarly, transparent films can be made of various transparent materials including but not limited to the polymers described above.

In conclusion, embodiments of the present invention may seek to the reduce costs and maximize scales of solar power plants through the use of elements employing minimal materials and low-cost materials. Elements of the solar power plant are able to be mass produced with existing technology, making them less expensive and better able to compete economically with existing fossil fuels.

The specification and drawings are, accordingly, to be regarded in an illustrative rather than a restrictive sense. It will, however, be evident that additions, subtractions, deletions, and other modifications and changes may be made thereunto without departing from the broader spirit and scope of the invention as set forth in the claims.

What is claimed is:

1. An apparatus comprising:
a reflective solar light concentrator having a physical shape; and
a feature formed in or on the reflective solar light concentrator to match optical behavior of the physical shape to optical behavior of a desired shape.

2. The apparatus of claim 1 further comprising an upper transparent portion that allows light to penetrate and reach the reflective solar light concentrator.

3. An apparatus comprising:
an upper transparent portion that allows light to penetrate;
a lower portion coupled to the upper transparent portion, the lower portion comprising a reflective concentrator that reflects the light that penetrates the upper transparent portion, the reflective concentrator having a physical shape; and
a feature formed in or on the reflective concentrator and configured to modify an optical characteristic of the physical shape to be substantially similar to an optical characteristic of a desired shape.

4. The apparatus of claim 3 wherein the reflective concentrator comprises a polymer and the feature comprises an embossed feature in the polymer.

5. The apparatus of claim 3 wherein a shape of the reflective concentrator is circular and the feature is annular.

6. The apparatus of claim 3 wherein a shape of the reflective concentrator is linear and the feature comprises a stripe.

7. The apparatus of claim 5 wherein the feature exhibits a step cross-section.

8. The apparatus of claim 5 wherein the feature exhibits a curved cross-section.

9. The apparatus of claim 3 wherein the feature comprises a local facet.

10. The apparatus of claim 3 wherein the reflective concentrator comprises an inflatable concentrator.

11. The apparatus of claim 10 wherein the physical shape comprises a Hencky-type surface.

12. The apparatus of claim 11 wherein the Hencky-type surface is configured to reflect incident light to a focal plane inside an inflation space defined between the reflective concentrator and the upper transparent portion.

13. The apparatus of claim 11 wherein the Hencky-type surface is configured to reflect incident light to a focal plane outside an inflation space defined between the reflective concentrator and the upper transparent portion.

14. The apparatus of claim 10 wherein the desired shape comprises an asphere.

15. The apparatus of claim 3 wherein the feature is operative to correct the optical characteristic of the physical shape when the lower portion is in an inflated form.

16. The apparatus of claim 3 wherein the upper transparent portion is coupled to the lower portion using a harness and the upper transparent portion, the lower portion, and harness together form an inflatable structure.

17. A method comprising:
forming a reflective solar light concentrator having a physical shape; and
forming a feature in or on the reflective solar light concentrator to modify an optical characteristic of the physical shape to be substantially similar to an optical characteristic of a desired shape.

18. The method of claim 17 further comprising forming an upper transparent portion that allows light to penetrate and reach the reflective solar light concentrator and coupling the upper transparent portion to the reflective solar light concentrator.

19. A method comprising:
forming an upper transparent portion that allows light to penetrate;
forming a lower portion comprising a reflective concentrator that reflects the light that penetrates the transparent portion, the reflective concentrator having a physical shape; and
forming a feature in a reflective concentrator to modify optical behavior of the physical shape to match optical behavior of a desired shape.

20. The method of claim 19 wherein the forming the feature comprises using an embossing technique.

21. The method of claim 20 wherein the forming the lower portion comprises directly embossing the feature onto a film and adding a reflective material to the film after the embossing to form the reflective concentrator.

22. The method of claim 20 wherein the forming the lower portion comprises:
adding a material to a film;
embossing in the material; and
adding a reflective material to the film to form the reflective concentrator.

23. The method of claim 20 wherein the forming the lower portion comprises:
embossing in a material;
forming a reflective film from the material; and
adding another material to the reflective film to form the reflective concentrator.

24. The method of claim 20 wherein the forming the lower portion comprises:
embossing a material to form a embossed material;
adding another material to the embossed material; and
forming a reflective surface using the embossed material after adding the other material to form the reflective concentrator.

25. The method of claim 19 wherein a perimeter of the reflective concentrator is circular and the feature is annular.

26. The method of claim 19 wherein a perimeter of the reflective concentrator is linear.

27. The method of claim 19 wherein the feature exhibits a step cross-section.

28. The method of claim 19 wherein the feature comprises a step cross-section.

29. The method of claim 19 wherein the feature comprises a local facet.

30. The method of claim 19 further comprising securing the upper transparent portion and the lower portion together to form a structure.

31. A method of fabricating a corrective optic for a reflective concentrator, the method comprising:
providing an optic element having a shape;
measuring a reflectance profile of the optic element;
comparing the measured reflectance profile with a desired reflectance profile; and
modifying the shape of the optic element to generate a modified optic element having the desired reflectance profile.

32. The method of claim 31 wherein modifying the shape of the optic element comprises changing a thickness profile of the optic element.

33. The method of claim 32 wherein changing the thickness profile further comprises screen printing the optic element with an ink.

34. The method of claim 32 wherein changing the thickness profile further comprises spray painting the optic element with an ink.

35. The method of claim 31 wherein modifying the shape of the optic element comprises fabricating one or more features on the optic element.

36. The method of claim 31 wherein modifying the shape of the optic element comprises changing a thickness profile of the optic element and fabricating one or more features on the optic element.

37. The method of claim 31 wherein the desired reflectance profile is an asphere.

38. The method of claim 31 wherein the desired reflectance profile is a parabolic profile.

39. The method of claim 31 wherein the shape of the provided optic element is a Hencky shape.

40. The method of claim 31 further comprising:
measuring the reflectance profile of the modified optic element;
determining whether the reflectance profile of the modified optic element is substantially similar to the desired reflectance profile; and
upon determining that the reflectance profile of the modified optic element is not substantially similar to the desired reflectance profile, further modifying the optic element.

41. The method of claim 40 wherein the desired reflectance profile corresponds to a predetermined threshold value.

42. A method comprising:
transmitting light through a transparent portion of a solar collector;
reflecting the transmitted light off a first reflective film having features disposed thereon, the features configured to modify the optical properties of the first reflective film to match optical properties of a second reflective film having a desired shape; and
capturing a substantial portion of the reflected light using a receiver that converts the captured reflected light into electrical energy.

43. An apparatus comprising:
an upper transparent film;
a lower film coupled to the upper transparent film to form an inflatable structure; and
one or more features located on a surface of the upper transparent film, the one or more features configured to focus incoming light onto a receiver located in an inflation space defined by the inflatable structure.

44. A method comprising:
forming an upper transparent film;
forming a lower non-reflective film;
coupling the upper transparent film to the lower non-reflective film to form an inflatable structure; and
forming one or more features on a surface of the upper transparent film, the one or more features configured to focus incoming light onto a receiver.

45. The method of claim 44 wherein forming the one or more features comprises embossing the upper transparent film.

46. The method of claim 44 wherein the one or more features are configured to match irradiance profile of the upper transparent film with a predetermined irradiance profile.
